(19) United States
(12) Patent Application Publication
(10) Pub. No.: US 2018/0321568 A1
(43) Pub. Date: Nov. 8, 2018

(54) ELECTROPHORETIC ELEMENT AND DISPLAY DEVICE

(71) Applicant: SHARP KABUSHIKI KAISHA, Sakai City, Osaka (JP)

(72) Inventor: HIROYUKI MORIWAKI, Sakai City (JP)

(73) Assignee: SHARP KABUSHIKI KAISHA, Sakai City ,Osaka (JP)

(21) Appl. No.: 15/774,704

(22) PCT Filed: Nov. 28, 2016
(86) PCT No.: PCT/JP2016/085197

§ 371 Date: May 9, 2018

(30) Foreign Application Priority Data
Dec. 4, 2015 (JP) 2015-237350

(51) Int. Cl. G02F 1/167; G09G 3/20; G09G 3/34; H01L 27/12

(52) U.S. Cl. CPC G02F 1/167; G09G 3/2003; G02F 1/136209; H01L 27/124; G09G 2310/08; G09G 3/3446

(57) ABSTRACT

An electrophoretic element includes a first substrate and a second substrate, an electrophoretic layer that is provided between the first substrate and the second substrate, and a plurality of pixels that are arrayed in a matrix. The electrophoretic element further includes a partition wall that partitions the electrophoretic layer into individual pixels. The first substrate includes, in each of the pixels, at least three electrodes to which mutually different potentials are capable of being applied. The partition wall includes a first part positioned between two pixels that are adjacent along one direction of a row direction and a column direction and a second part positioned between two pixels that are adjacent along the other direction. In a case where one of two pixels that are adjacent via the first part of the partition wall is set as a first pixel and the other is set as a second pixel, the first part of the partition wall at least partially covers each of one electrode of the first pixel and one electrode of the second pixel.

### TECHNICAL FIELD

The present invention relates to an electrophoretic element. Moreover, the invention also relates to a display device including the electrophoretic element.

### BACKGROUND ART

In recent years, an electrophoretic display is attracting attention as a reflective display device that is excellent in low power consumption and visibility.

NPL 1 proposes an electrophoretic display capable of not only black and white display but also color display. FIG. 28 illustrates an electrophoretic display 800 proposed in NPL 1, FIG. 28 is a cross-sectional view schematically illustrating a region that corresponds to a pixel of the electrophoretic display 800.

As illustrated in FIG. 28, the electrophoretic display 800 includes a lower glass substrate 801 and an upper glass substrate 802, and oil 831 that is sealed therebetween. In the oil 831, first particles 832P and second particles 832N are dispersed. The first particles 832P are charged with positive polarity, and the second particles 832N are charged with negative polarity. The first particles 832P and the second particles 832N have colors (for example, magenta and green) which are in a complementary relation to each other.

A first moving electrode 811, a second moving electrode 812, and a dating electrode 813 are provided on the lower glass substrate 801. The first moving electrode 811 is arranged in one end part of a pixel, and the second moving electrode 812 is arranged in the other end part of the pixel. The gating electrode 813 is arranged between the first moving electrode 811 and the second moving electrode 812. Note that, the gating electrode 813 is positioned in a vicinity of the first moving electrode 811. That is, an interval between the first moving electrode 811 and the gating electrode 813 is considerably narrower than an interval between the gating electrode 813 and the second moving electrode 812. When there is a potential difference between two adjacent electrodes among the first moving electrode 811, the second moving electrode 812, and the gating electrode 813, a horizontal electric field is generated between the electrodes, and the first particles 832P and/or the second particles 832N move in accordance with the horizontal electric field. A region between the gating electrode 813 and the second moving electrode 812 is a region that contributes to display. A rear surface reflecting material 850 is arranged on a rear surface side of the lower glass substrate 801.

A display principle of the electrophoretic display 800 will be described here also with reference to FIGS. 29(a), (b), and (c).

In the electrophoretic display 800, when a magnitude relation of potentials that are applied to the first moving electrode 811, the second moving electrode 812, and the gating electrode 813 is controlled, switching is performed between four states illustrated in FIG. 28 and FIGS. 29(a), (b), and (c).

In the state illustrated in FIG. 28, both the first particles 832P and the second particles 832N are positioned between the gating electrode 813 and the second moving electrode 812. Therefore, in this state, display by subtractive color mixture of the color of the first particles 832P and the color of the second particles 832N, that is, black display is performed.

In the state illustrated in FIG. 29(a), neither the first particles 832P nor the second particles 832N is positioned between the gating electrode 813 and the second moving electrode 812. Therefore, in this state, display with light reflected by the rear surface reflecting material 850, that is, white display is performed.

In the state illustrated in FIG. 29(b), only the second particles 832N of the first particles 832P and the second particles 832N are positioned between the gating electrode 813 and the second moving electrode 812. Therefore, in this state, display of the color (for example, green) of the second particles 832N is performed.

In the state illustrated in FIG. 29(c), only the first particles 832P of the first particles 832P and the second particles 832N are positioned between the gating electrode 813 and the second moving electrode 812. Therefore, in this state, display of the color (for example, magenta) of the first particles 832P is performed.

In this manner, in the electrophoretic display 800 of NPL 1, color display is realized by using three electrodes 811, 812, and 813 that generate the horizontal electric field and two types of particles 832P and 832N that are charged with mutually different polarity.

### CITATION LIST

### Non Patent Literature

NPL 1: S. Mukherjee and seven others, “The Biprimary Color System for E-Paper: Doubling Color Performance Compared to RGBW”, SID Digest, 2014, pp. 869-872

### SUMMARY OF INVENTION

### Technical Problem

However, in the electrophoretic display 800 of NPL 1, the particles 832P and 832N in a pixel are affected by an electric field of an adjacent pixel. For example, as illustrated in FIG. 30, when there is a potential difference between the first moving electrode 811 of a certain pixel (hereinafter, referred to as a “first pixel”) Px1 and the second moving electrode 812 of a pixel (hereinafter, referred to as a “second pixel”) Px2 which is adjacent to the first pixel Px1, a horizontal electric field (indicated by an electric line of force E1 in the figure) is generated therebetween, and the horizontal electric field extends to an inside of the first pixel Px1. Moreover, when there is a potential difference between the second moving electrode 812 of the first pixel Px1 and the first moving electrode 811 of another pixel (hereinafter, referred to as a “third pixel”) Px3 which is adjacent to the first pixel Px1, a horizontal electric field (indicated by an electric line of force E2 in the figure) is generated therebetween, and the horizontal electric field extends to the inside of the first pixel Px1.

As above, in an electrophoretic display using a horizontal electric field, there is a possibility that particles in a pixel are affected by an electric field of an adjacent pixel and a suitable display operation is disturbed. This phenomenon is hereinafter referred to as crosstalk in some cases.

The invention is made in view of the aforementioned problem, and an object thereof is to prevent occurrence of crosstalk in an electrophoretic element using a horizontal electric field.

### Solution to Problem

Aa electrophoretic element of an embodiment of the invention is an electrophoretic element including: a first substrate and a second substrate that face each other; an electrophoretic layer that is provided between the first substrate and the second substrate; and a plurality of pixels that are arrayed in a matrix having a plurality of rows and a plurality of columns, and each of which includes an opening region through which light passes from the electrophoretic layer toward a front surface side, in which a partition wall that is provided between the first substrate and the second substrate and partitions the electrophoretic layer into individual pixels is further included, the first substrate includes, in each of the plurality of pixels, at least three electrodes to which mutually different potentials are capable of being applied, the partition wall includes a first part positioned between two pixels that are adjacent along one direction of a row direction and a column direction and a second part positioned between two pixels that are adjacent along the other direction of the row direction and the column direction, and in a case where one of two pixels that are adjacent via the first part of the partition wall is set as a first pixel and the other is set as a second pixel, the first part of the partition wall at least partially covers each of a pair of electrodes, which is composed of one electrode of at least three electrodes of the first pixel and one electrode of at least three electrodes of the second pixel.

In a certain embodiment, the electrophoretic layer includes, in each of the plurality of pixels, a dispersion medium and a plurality of types of electrophoretic particles that are dispersed in the dispersion medium.

In a certain embodiment, the plurality of types of electrophoretic particles include first electrophoretic particles and second electrophoretic particles that are charged with same polarity and have mutually different threshold characteristics.

In a certain embodiment, the electrophoretic element is able to position, in the opening region, two or more types of electrophoretic particles among the plurality of types of electrophoretic particles by controlling the potentials of the at least three electrodes.

In a certain embodiment, the plurality of types of electrophoretic particles include third electrophoretic particles that are charged with same polarity as that of the first electrophoretic particles and the second electrophoretic particles and have threshold characteristics different from those of the first electrophoretic particles and the second electrophoretic particles, and fourth electrophoretic particles that are charged with polarity different from that of the first electrophoretic particles, the second electrophoretic particles, and the third electrophoretic particles, and the at least three electrodes included in the first substrate are four or more electrodes to which mutually different potentials are capable of being applied.

In a certain embodiment, the plurality of types of electrophoretic particles include third electrophoretic particles and fourth electrophoretic particles that are charged with polarity different from that of the first electrophoretic particles and the second electrophoretic particles and have mutually different threshold characteristics, and the at least three electrodes included in the first substrate are four or more electrodes to which mutually different potentials are capable of being applied.

In a certain embodiment, the plurality of types of electrophoretic particles include first electrophoretic particles and second electrophoretic particles that are charged with mutually different polarity.

In a certain embodiment, the plurality of types of electrophoretic particles include electrophoretic particles having a cyan color, electrophoretic particles having a magenta color, electrophoretic particles having a yellow color, and electrophoretic particles having a black color.

In a certain embodiment, the electrophoretic particles having the cyan color, the electrophoretic particles having the magenta color, and the electrophoretic particles having the yellow color are charged with mutually same polarity and have mutually different threshold characteristics, and the electrophoretic particles having the black color is charged with polarity different from that of the electrophoretic particles having the cyan color, the electrophoretic particles having the magenta color, or the electrophoretic particles having the yellow color.

In a certain embodiment, the pair of electrodes that are covered with the first part are arranged to extend approximately in parallel to each other.

In a certain embodiment, the first part has a shape including two sides that are approximately parallel in the other direction, as viewed from a substrate surface normal direction of the first substrate, and each of the pair of electrodes that are covered with the first part is arranged in a vicinity of each of the two sides.

In a certain embodiment, the partition wall further includes a third part that connects the first part and the second part, and a part of each of the pair of electrodes is covered with the third part.

In a certain embodiment, a distance between the pair of electrodes is equal to or shorter than a distance between any two electrodes, which are adjacent to each other, among the at least three electrodes of each of the pixels.

In a certain embodiment, a width of each of the electrodes, which are covered with the first part is equal to or shorter than a width of an electrode, which is not covered with the first part, among the at least three electrodes of each of the pixels.

In a certain embodiment, the electrophoretic element further includes a light shielding layer that is positioned closer to a front surface side than the electrophoretic layer, and the light shielding layer includes a first light shielding region that overlaps with the first part of the partition wall and a second light shielding region that extends from the first light shielding region in the one direction.

In a certain embodiment, each of the pair of electrodes includes a part that is not covered with the first part of the partition wall.

In a certain embodiment, a width of the part of each of the pair of electrodes, which is not covered with the first part of the partition wall, is equal to or shorter than a width of a part of each of the pair of electrodes, which is covered with the first part of the partition wall.

In a certain embodiment, the at least three electrodes include at least one electrode provided in the opening region.

In a certain embodiment, the at least one electrode provided in the opening region is a reflection electrode having a light reflecting property.

In a certain embodiment, the electrophoretic element further Includes a light reflecting layer or a light absorbing layer each of which is provided, in the opening region, closer to a rear surface side than the electrophoretic layer.

In a certain embodiment, the electrophoretic element is able to perform active matrix drive.

A display device of an embodiment of the invention includes an electrophoretic element having any of the above-described configurations.

### Advantageous Effects of Invention

According to an embodiment of the invention, it is possible to prevent occurrence of crosstalk in an electrophoretic element using a horizontal electric field.

### BRIEF DESCRIPTION OF DRAWINGS

FIG. 1 is a cross-sectional view schematically Illustrating an electrophoretic element (display device) 100 according to an embodiment of the invention.

FIG. 2 is a plan view schematically illustrating a partition wall 40 included in the electrophoretic element 100.

FIG. 3 is a graph indicating an example of threshold characteristics of cyan particles 32C, magenta particles 32M, yellow particles 32Y, and black particles 32B that are included in an electrophoretic layer 30 of the electrophoretic element 100.

FIGS. 4(a) and (b) are views for explaining a reason why different thresholds are able to be manifested when charge amounts of electrophoretic particles 32 are different.

FIGS. 5(a) and (b) are views for explaining a display sequence of white display.

FIGS. 6(a) and (b) are views for explaining a display sequence of black display.

FIGS. 7(a) to (d) are views for explaining a display sequence of cyan display.

FIGS. 8(a) to (d) are views for explaining a display sequence of magenta display.

FIGS. 9(a) to (c) are views for explaining a display sequence of yellow display.

FIGS. 10(a) to (c) are views for explaining a display sequence of green display.

FIGS. 11(a) to (d) are views for explaining a display sequence of blue display.

FIGS. 12(a) to (c) are views for explaining a display sequence of red display.

FIGS. 13(a) to (d) are views for explaining a display sequence of magenta gradation display.

FIGS. 14(a) to (d) are views for explaining a display sequence of red gradation display.

FIGS. 15(a) to (c) are cross-sectional views schematically illustrating electrophoretic elements 900A, 900B, and 900C of comparative examples 1, 2, and 3, respectively.

FIG. 16 is a view for explaining an effect of the electrophoretic element 100 according to the embodiment of the invention.

FIG. 17 is a view schematically illustrating the electrophoretic element (display device) 100 of an active matrix drive type.

FIG. 18 is a plan view schematically illustrating the electrophoretic element 100 of the active matrix drive type.

FIGS. 19(a) and (b) are views schematically illustrating the electrophoretic element 100 of the active matrix drive type, and are cross-sectional views taken along a 19A-19A′ line and a 19B-19B′ line in FIG. 18, respectively.

FIG. 20 is a cross-sectional view illustrating another configuration of the electrophoretic element 100 according to the embodiment of the invention.

FIGS. 21(a) and (b) are views illustrating an example of a pixel pitch and an electrode size of a case where resolution is 52 ppi (case where a diagonal length is 42 inches, a pixel number in a horizontal direction is 1920, and a pixel number in a vertical direction is 1080).

FIGS. 22(a) and (b) are views illustrating an example of a pixel pitch and an electrode size of a case where resolution is 160 ppi (case where the diagonal length is 6.3 inches, the pixel number in the horizontal direction is 800, and the pixel number in the vertical direction is 600).

FIGS. 23(a) and (b) are views illustrating an example of a pixel pitch and an electrode size of a case where resolution is 326 ppi (case where the diagonal length. is 4.7 inches, the pixel number in the horizontal direction is 1334, and the pixel number in the vertical direction is 750).

FIG. 24 is a cross-sectional view illustrating still another configuration of the electrophoretic element 100 according to the embodiment of the invention.

FIGS. 25(a) and (b) are cross-sectional views schematically illustrating an electrophoretic element (display device) 200 according to an embodiment of the invention.

FIGS. 26(a) and (b) are views illustrating an example of a pixel pitch and an electrode size of a case where resolution is 52 ppi (case where the diagonal length is 42 inches, the pixel number in the horizontal direction is 1920, and the pixel number in the vertical direction is 1080).

FIG. 27 is a cross-sectional view schematically illustrating an electrophoretic element (display device) 300 according to an embodiment of the invention.

FIG. 28 is a cross-sectional view schematically illustrating a region corresponding to a pixel of an electrophoretic display 800 of NPL 1.

FIGS. 29(a) to (c) are views for explaining a display principle of the electrophoretic display 600 of NPL 1.

FIG. 30 is a view for explaining a reason why crosstalk is caused in the electrophoretic display 800 of NPL 1.

### DESCRIPTION OF EMBODIMENTS

Embodiments of the invention will be described below with reference to the drawings. Note that, the invention is not limited to the following embodiments.

### Embodiment 1

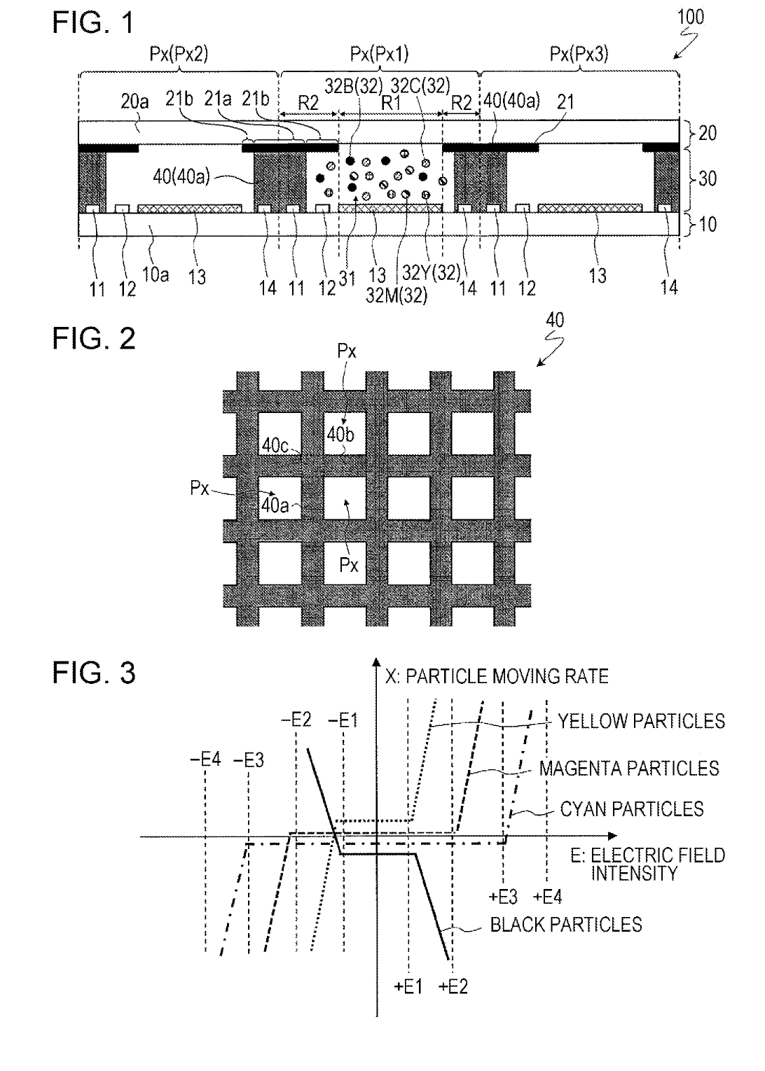

FIG. 1 illustrates an electrophoretic element (display device) 100 of the present embodiment. FIG. 1 is a cross-sectional view schematically illustrating three pixels Px of the electrophoretic element 100. Hereinafter, in some cases, a pixel Px1 in the center of FIG. 1 is referred to as a “first pixel”, a pixel Px2 that is adjacent to the first pixel Px1 on a left side is referred to as a “second pixel”, and a pixel Px3 that is positioned on a right side of the first pixel Px1 (that is, positioned on a side of the first pixel Px1 opposite to the side on which the second pixel Px2 is positioned) is referred to as a “third pixel”.

As illustrated in FIG. 1, the electrophoretic element 100 includes a first substrate 10 and a second substrate 20 that face each other, and an electrophoretic layer 30 that is provided between the first substrate 10 and the second substrate 20. In an example illustrated in FIG. 1, the first substrate 10 is arranged on a rear surface side (side opposite to a side of an observer), and the second substrate 20 is arranged on a front surface side (side of the observer).

Moreover, the electrophoretic element 100 has a plurality of pixels Px that are arrayed in a matrix having a plurality of rows and a plurality of columns. Each of the plurality of pixels Px includes an opening region R1. The opening region R1 is a region through which light passes from the electrophoretic layer 30 toward the front surface side.

Further, the electrophoretic element 100 includes a partition wall 40 that partitions the electrophoretic layer 30 into individual pixels Px and a light shielding layer 21 that is positioned closer to the front surface side than the electrophoretic layer 30.

The partition wall 40 is provided between the first substrate 10 and the second substrate 20. FIG. 2 illustrates a plane structure of the partition wall 40. FIG. 2 is a plan view illustrating the partition wall 40 as viewed from a substrate surface normal direction of the first substrate 10.

As illustrated in FIG. 2, the partition wall 40 is lattice-shaped. More specifically, the partition wall 40 has column parts 40a each of which is positioned between two pixels Px that are adjacent along a row direction, row parts 40b each of which is positioned between two pixels Px that are adjacent along a column direction, and connection parts 40c each of which connects each of the column parts 40a and each of the row parts 40b. FIG. 1 illustrates three pixels Px that are continuous along the row direction, and FIG. 1 illustrates the column parts 40a of the partition wall 40.

The light shielding layer 21 shields a region R2, which is a region other than the opening region R1, of each of the pixels Px from light. That is, it is possible to say that a region that is not shielded from light by the light shielding layer 21 is the opening region R1 and the light shielding layer 21 prescribes the opening region R1. In the present embodiment, the light shielding layer 21 includes a region (hereinafter, referred to as a “first light shielding region”) 21a which overlaps with the column part 40a of the partition wall 40 and a region (hereinafter, referred to as a “second light shielding region”) 21b which extends from the first light shielding region 21a in the row direction.

The electrophoretic layer 30 has, in each of the pixels Px, a dispersion medium 31 and a plurality of types of electrophoretic particles 32 that are dispersed in the dispersion medium 31. In the present embodiment, the plurality of types of electrophoretic particles 32 include electrophoretic particles (cyan particles) 32C which have a cyan color, electrophoretic particles (magenta particles) 32M which have a magenta color, electrophoretic particles (yellow particles) 32Y which have a yellow color, and electrophoretic particles (black particles) 32B which have a black color.

The cyan particles 320, the magenta particles 32M, and the yellow particles 32Y are charged with mutually the same polarity (here, positive polarity), and have mutually different threshold characteristics. The black particles 32B are charged with polarity (here, negative polarity) which is different from that of the cyan particles 32C, the magenta particles 32M, or the yellow particles 32Y.

The first substrate 10 has, in each of the pixels Px, four (four types of) electrodes 11, 12, 13, and 14 to which mutually different potentials are capable of being applied. The above-described four electrodes, specifically, the first electrode 11, the second electrode 12, the third electrode 13, and the fourth electrode 14 are supported by a transparent substrate 10a. An insulating layer (not illustrated here) is formed so as to cover the first electrode 11, the second electrode 12, the third electrode 13, and the fourth electrode 14.

In the example illustrated in FIG. 1, the first electrode 11, the second electrode 12, the third electrode 13, and the fourth electrode 14 are arranged in this order along a certain direction. (direction from a left side to a right side in FIG. 1) which is parallel to a substrate surface of the first substrate 10. The first substrate 11, the second substrate 12, and the fourth substrate 14 are provided in the region R2 which is shielded from light by the light shielding layer 21. On the contrary, the third electrode 13 is provided in the opening region R1. The third electrode 13 is a reflection electrode having a light reflecting property.

The second substrate 20 includes a transparent substrate 20a. Here, the light shielding layer 21 is arranged in an electrophoretic layer 30 at a side of the transparent substrate 20a.

In the present embodiment, the column part 40a of the partition wall 40 covers two electrodes 11 and 14 as illustrated in FIG. 1. For example, the column part 40a that is positioned between the first pixel Px1 and the second pixel Px2 in FIG. 1 covers the first electrode 11 (which is an electrode closest to the second pixel Px2 among the four electrodes 11, 12, 13, and 14 of the first pixel Px1) of the First pixel Px1 and the fourth electrode 14 (which is an electrode closest to the first pixel Px1 among the four electrodes 11, 12, 13, and 14 of the second pixel Px2) of the second pixel px2. Moreover, the column part 40a that is positioned between the first pixel Px1 and the third pixel Px3 in FIG. 1 covers the fourth electrode 14 (which is an electrode closest to the third pixel Px3 among the four electrodes 11, 12, 13, and 14 of the first pixel Px1) of the first pixel Px1 and the first electrode 11 (which is an electrode closest to the first pixel among the four electrodes 11, 12, 13, and 14 of the third pixel Px3) of the third pixel Px3. That is, the column part 40a of the partition wall 40 covers a pair of electrodes, which is composed of one electrode among four electrodes 11, 12, 13, and 14 of one pixel Px of two pixels that are adjacent to each other via the column part 40a and one electrode of four electrodes 11, 12, and 14 of the other pixel Px.

The electrophoretic element 100 is able to apply a horizontal electric field to the electrophoretic layer 30 by controlling potentials of the four electrodes 11, 12 13, and 14, and is thereby able to position, in the opening region R1, one type or two Cr more types of electrophoretic particles 32 among the plurality of types of electrophoretic particles 32. That is, not juxtaposition color mixture (that is, color mixture by pixels Px) but subtractive color mixture (superposing colors) in one pixel Px is enabled. Hereinafter, a display principle of the electrophoretic element 100 will be described. First, threshold characteristics of the electrophoretic particles 32 will be described.

### [Threshold Characteristics of Electrophoretic Particles]

FIG. 3 illustrates examples of threshold characteristics of the cyan particles 32C, the magenta particles 32M, the yellow particles 32Y, and the black particles 32B. FIG. 3 is a graph in which a horizontal axis indicates an electric field intensity E and a vertical axis indicates a particle moving rate X. Absolute values |E1|, |E2|, |E3|, and |E4| of electric field intensities +E1, +E2, +E3, +E4, −E1, −E2, −E3, and −E4 which are indicated in FIG. 3 satisfy a relation of |E1|<|E2|<|E3|<|E4|. As is clear from FIG. 3, the cyan particles 32C move in a positive direction when +E3<E is satisfied, and move in a negative direction when E<−E3 is satisfied. Similarly, the magenta particles 32M move in the positive direction when +E2<E is satisfied, and move in the negative direction when E<−E2 is satisfied, and the yellow particles 32Y move in the positive direction when. +E1<E is satisfied, and move in the negative direction when E<−E1 is satisfied. Moreover, the black particles 32B move in the negative direction when +E1<E is satisfied, and move in the positive direction when E<−E1 is satisfied. In the present specification, a voltage (electric field intensity) with which the electrophoretic particles 32 start moving is referred to as a threshold voltage (threshold electric field intensity) in some cases.

In this manner, the cyan particles 32C, the magenta particles 32M, and the yellow particles 32Y are charged with mutually the same polarity, and threshold voltages thereof are mutually different. This is because charge amounts of the cyan particles 32C, the magenta particles 32M, and the yellow particles 32Y are mutually different.

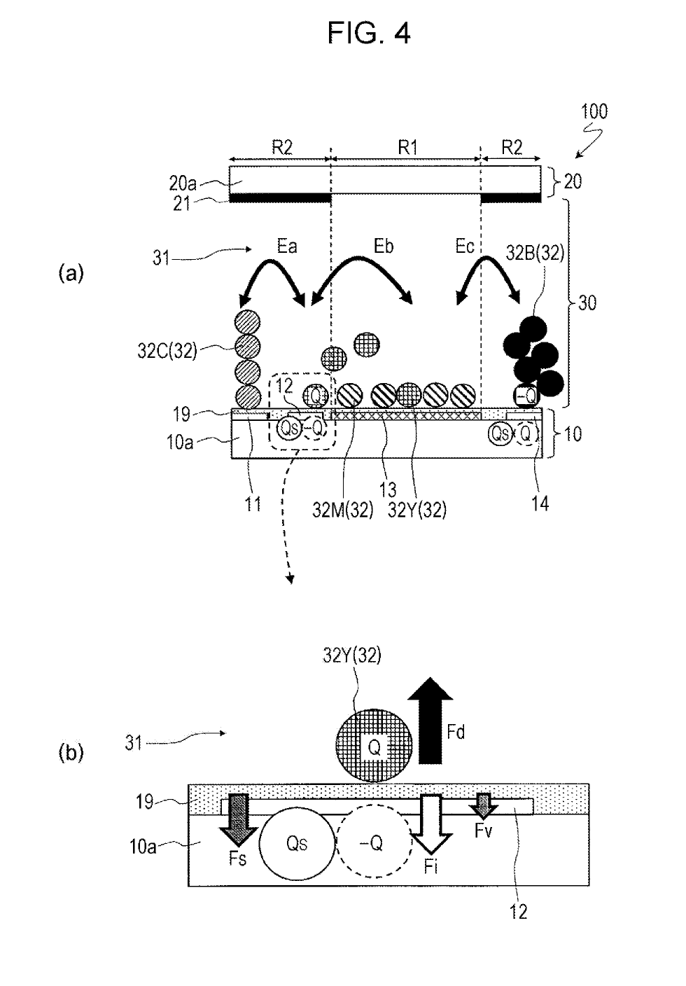

Here, a reason why the different thresholds are able to be manifested when the charge amounts are different will be described with reference to FIGS. 4(a) and (b). FIG. 4(a) is a cross sectional view schematically illustrating a state where a horizontal electric field is applied to the electrophoretic layer 30, and FIG. 4(b) is an enlarged view of a region surrounded by a dotted line in FIG. 4(a). Note that, the partition wall 40 is omitted in FIGS. 4(a) and (b) for simplification of description. Moreover, an insulating layer 19 that covers the first electrode 11, the second electrode 12, the third electrode 13, and the fourth electrode 14 is illustrated in FIGS. 4(a) and (b).

In the electrophoretic element 100, the four electrodes 11, 12, 13, and 14 to which mutually different potentials are capable of being applied are provided in the first substrate 10, so that it is possible to generate three independent electric fields in the electrophoretic layer 30 as illustrated in FIG. 4(a). Specifically, between the first electrode 11 and. the second electrode 12, an electric field (indicated by a double-headed arrow Ea in FIG. 4(a)) according to a potential difference therebetween is generated. Moreover, between the second electrode 12 and the third electrode 13, an electric field (indicated by a double-headed arrow Eb in FIG. 4(a)) according to a potential difference therebetween is generated, and, between the third electrode 13 and the fourth electrode 14, an electric field (indicated by a double-headed arrow Ec in FIG. 4 (a)) according to a potential difference therebetween is generated.

Here, two types of force that acts on the electrophoretic particles 32 positioned on the electrode, that is, electrostatic force Fd that acts so as to separate the electrophoretic particles 32 from the electrode and attraction (that is, force that causes the electrophoretic particles 32 to stay on the electrode) Fa between the electrophoretic particles 32 and the first substrate 10 will be considered. FIG. 4(b) exemplifies a yellow particle 32Y on the second electrode 12.

The above-described electrostatic force Fd is expressed as the following formula (1). Here, in the formula (1), Q indicates an electric charge of the electrophoretic particles 32 and E indicates an electric field generated in the electrophoretic layer 30.

Fd=Q·E (1)

Moreover, the above-described attraction Fa is expressed as the following formula (2). Here, in the formula (2), Fv indicates van der Waals force, Fi indicates image force, and Fs indicates electrostatic force between an electric charge of an insulator (here, the insulating layer 19) (or an electric charge of the electrode) and the electrophoretic particles 32.

Fa=Fv+Fi+Fs (2)

The image force Fi is expressed as the following formula (3), and the electrostatic force Fs is expressed as the following formula (4). Here, C₁ in the formula (3) indicates a constant, and, in the formula. (4), C₂ indicates a constant and Qs indicates the electric charge of the insulator.

Fi=C₁·Q² (3)

Fs=C₂·Q·Qs (4)

Here, the threshold voltage of the electrophoretic particles 32 corresponds to an electric field Eth when the electrostatic force Fd and the attraction Fa are in balance (in the case of the following formula (5)).

Fd=Fa (5)

The following formula (6) is able to be obtained from the aforementioned formulas (1) to (5), so that the electric field Eth corresponding to the threshold voltage is expressed as the following formula (7) obtained by modifying the formula (6). From the formula (7), it is found that the electric field Eth corresponding to the threshold voltage varies in accordance with the electric charge Q, that is, the charge amount of the electrophoretic particles 32.

Q·Eth=Fv+C₁·Q²+C₂·Q·Qs (6)

Eth=Fv/Q+C₁·Q+C₂·Qs (7)

Next, display sequences of white display and black display will be described. Note that, in description below, six potential levels of a[V], b[V], c[V], d[V], e[V], and f[] will be mentioned in addition to a ground potential GND (0 V). The ground potential GND and the six potential levels satisfy a relation of a<b<c<0<d<e<f. In a case where there is one difference between potential levels of adjacent electrodes (for example, in a case where the potentials of a[V] and. b[V] are respectively applied to two adjacent electrodes), a potential gradient corresponding to the electric field intensity E2 (+E2 or −E2) is formed between the electrodes. Similarly, in a case where there are two differences between potential levels of adjacent electrodes (for example, in a case where the potentials of a[V] and c[V] are respectively applied to two adjacent electrodes), a potential gradient corresponding to the electric field intensity E3 (+E3 or −E3) is formed between the electrodes, and in a case where there are three differences between potential levels of adjacent electrodes (for example, in a case where the potential of a [V] and the ground potential GND are respectively applied to two adjacent electrodes), a potential gradient corresponding to the electric field intensity E4 (+E4 or −E4) is formed between the electrodes.

### [White Display (Reset)]

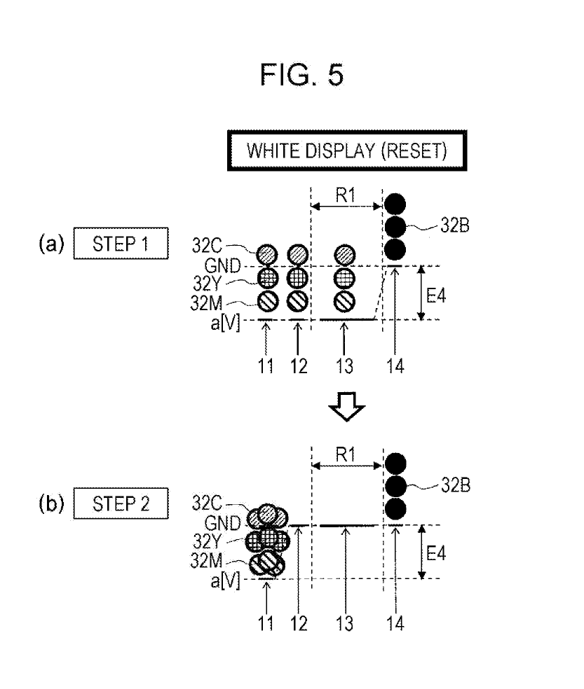

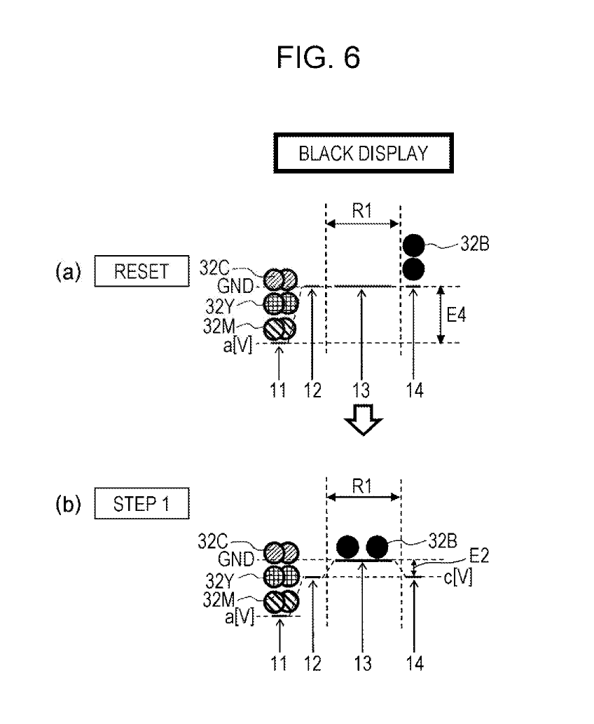

FIGS. 5(a) and (b) are views for explaining the display sequence of white display. First, as illustrated in FIG. 5(a), potentials of the first electrode 11, the second electrode 12, and the third electrode 13 are set to be a[V] and a potential of the fourth electrode 14 is set to be the ground potential GND (step 1). At this time, the potential gradient corresponding to the electric field intensity E4 is formed between the third electrode 13 and the fourth electrode 14, so that the cyan particles 32C, the magenta particles 32M, and the yellow particles 32Y are positioned on the first electrode 11, the second electrode 12, and the third electrode 13, and the black particles 32B are positioned on the fourth electrode 14.

Thereafter, as illustrated in FIG. 5(b), the potentials of the second electrode 12 and the third electrode 13 are set to be the ground potential GND (step 2). At this time, the potential gradient corresponding to the electric field intensity E4 is formed between the first electrode 11 and the second electrode 12, so that the cyan particles 32C, the magenta particles 32M, and the yellow particles 32Y that are on the second electrode 12 and the third electrode 13 are transferred onto the first electrode 11. Since no electrophoretic particle 32 is positioned in the opening region R1 (on the third electrode 13) in this state, external light (ambient light) incident on the electrophoretic layer 30 from the side of the observer is reflected by the third electrode 13, and white display is performed.

In the electrophoretic element 100, switching of display from one color to another color is basically performed after such a state of white display. Therefore, the white display is also able to be referred to as a reset operation.

### [Black Display]

FIGS. 6(a) and (b) are views for explaining the display sequence of black display. First, as illustrated in FIG. 6(a), the potentials are applied in the same manner as the state of the white display to the first electrode 11, the second electrode 12, the third electrode 13, and the fourth electrode 14 to perform reset.

Thereafter, as illustrated in FIG. 6(b), the potentials of the second electrode 12 and the fourth electrode 14 are set to be c[V] (step 1). At this time, the potential gradient corresponding to the electric field intensity E2 is formed between the third electrode 13 and the fourth electrode 14, so that the black particles 32B on the fourth. electrode 14 move to the opening region R1 (onto the third electrode 13). Therefore, black display is performed in this state. Moreover, the potential gradient corresponding to the electric field intensity E2 is formed between the second electrode 12 and the third electrode 13 at this time, so that the black particles 32B that have moved to the opening region R1 are prevented from further moving onto the second electrode 12.

Subsequently, display sequences of monochrome display of each of cyan, magenta, and yellow will be described.

### [Cyan Display]

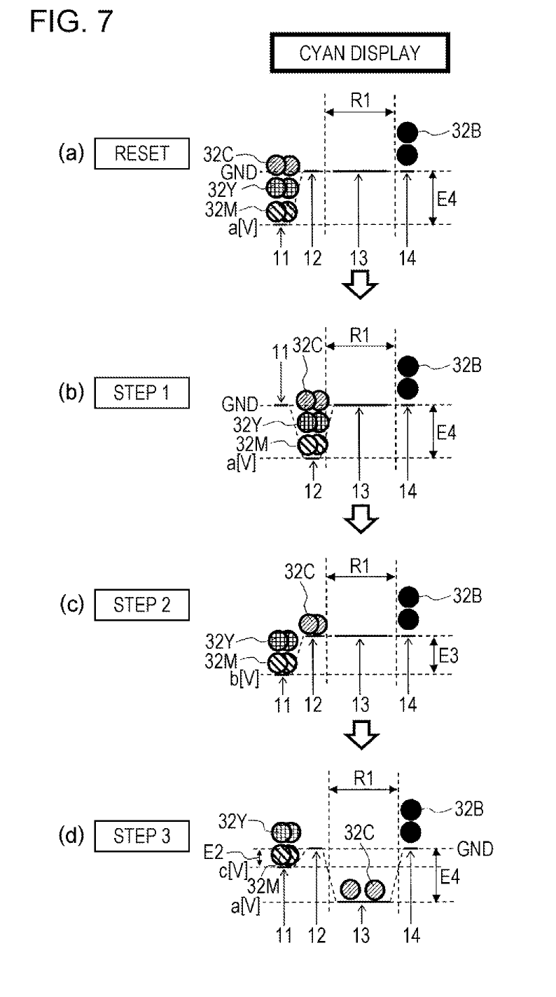

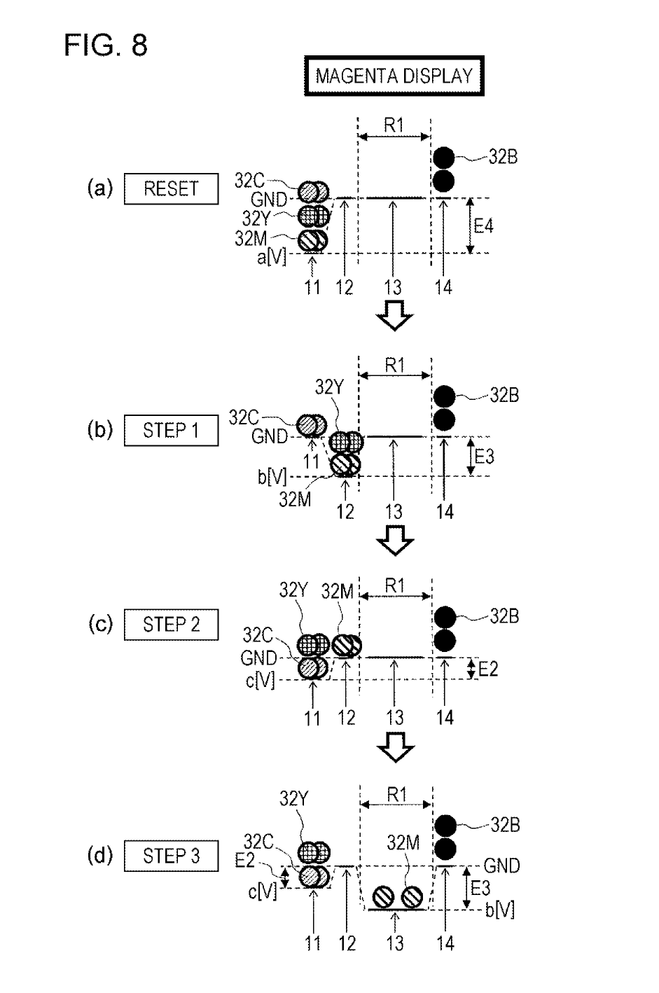

FIGS. 7(a) to (d) are views for explaining the display sequence of cyan display. First, as illustrated in FIG. 7(a), the potentials are applied in the same manner as the state of the white display to the first electrode 11, the second electrode 12, the third electrode 13, and the fourth electrode 14 to perform reset.

Next, as illustrated in FIG. 7(b), the potential of the first electrode 11 is set to be the ground potential GND and the potential of the second electrode 12 is set to be a[V] (step 1). At this time, the potential gradient corresponding to the electric field intensity 54 is formed between the first electrode 11 and the second electrode 12. Therefore, the cyan particles 32C, the magenta particles 32M, and the yellow particles 32Y that are on the first electrode 11 move onto the second electrode 12.

Subsequently, as illustrated in FIG. 7(c), the potential of the first electrode 11 is set to be b[V] and the potential of the second electrode 12 is set to be the around potential GND (step 2). At this time, the potential gradient corresponding to the electric field intensity 53 is formed between the first electrode 11 and the second electrode 12, so that the magenta particles 32M and the yellow particles 32Y that are on the second electrode 11 move onto the first electrode 11 (the cyan particles 32C stay on the second electrode 12).

Thereafter, as illustrated in FIG. 7(d), the potential of the first electrode 11 is set to be c[V] and the potential of the third electrode 13 is set to be a[V] (step 3). At this time, the potential gradient corresponding to the electric field intensity E4 is formed between the second electrode 12 and the third electrode 13, so that the cyan particles 32C on the second electrode 12 move to the opening region R1 (onto the third electrode 13). Therefore, cyan display is performed in this state.

### [Magenta Display]

FIGS. 8(a) to (d) are views for explaining the display sequence of magenta display. First, as illustrated in FIG. 8(a), the potentials are applied in the same manner as the state of the white display to the first electrode 11, the second electrode 12, the third electrode 13, and the fourth electrode 14 to perform reset.

Next, as illustrated in FIG. 8(b), the potential of the first electrode 11 is set to be the ground potential GND and the potential of the second electrode 12 is set to be b[V] (step 1). At this time, the potential gradient corresponding to the electric field intensity E3 is formed between the first electrode 11 and the second electrode 12, so that the magenta particles 32M and the yellow particles 32Y that are on the first electrode 11 move onto the second electrode 12 (the cyan particles 32C stay on the first electrode 11).

Subsequently, as illustrated in FIG. 8(c), the potential of the first electrode 11 is set to be c[V] and the potential of the second electrode 12 is set to be the ground potential GND (step 2). At this time, the potential gradient corresponding to the electric field intensity E2 is formed between the first electrode 11 and the second electrode 12, so that the yellow particles 32Y that are on the second electrode 12 move onto the first electrode 11 (the magenta particles 32M stay on the second electrode 12).

Thereafter, as illustrated in FIG. 8(d), the potential of the third electrode 13 is set to be b [V] (step). At this time, the potential gradient corresponding to the electric field intensity E3 is formed between the second electrode 12 and the third electrode 13, so that the magenta particles 32M on the second electrode 12 move to the opening region R1 (onto the third electrode 13). Therefore, magenta display is performed in this state.

### [Yellow Display]

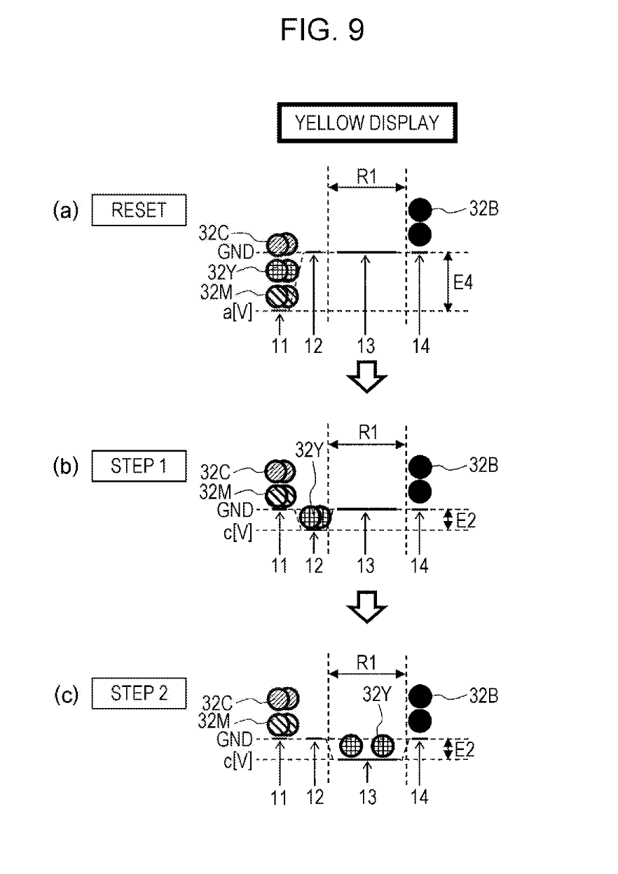

FIGS. 9(a) to (c) are views for explaining the display sequence of yellow display. First, as illustrated in FIG. 9(a), the potentials are applied in the same manner as the state of the white display to the first electrode 11, the second electrode 12, the third electrode 13, and the fourth electrode 14 to perform reset.

Next, as illustrated in FIG. 9(b), the potential of the first electrode 11 is set to be the ground potential GND and the potential of the second electrode 12 is set to be c[V] (step 1). At this time, the potential gradient corresponding to the electric field intensity E2 is formed. between the first electrode 11 and the second electrode 12, so that the yellow particles 32Y that are on the first electrode 11 move onto the second electrode 12.

Subsequently, as illustrated in FIG. 9(c), the potential of the second electrode 12 is set to be the ground potential GND and the potential of the third electrode 13 is set to be c[V] (step 2). At this time, the potential gradient corresponding to the electric field intensity E2 is formed between the second electrode 12 and the third electrode 13, so that the yellow particles 32Y that are on the second electrode 12 move to the opening region R1 (onto the third electrode 13). Therefore, yellow display is performed in this state.

Subsequently, display sequences of green display (mixed color display of cyan and yellow), blue display (mixed color display of cyan and magenta), and red display (mixed color display of magenta and yellow) will be described.

### [Green Display]

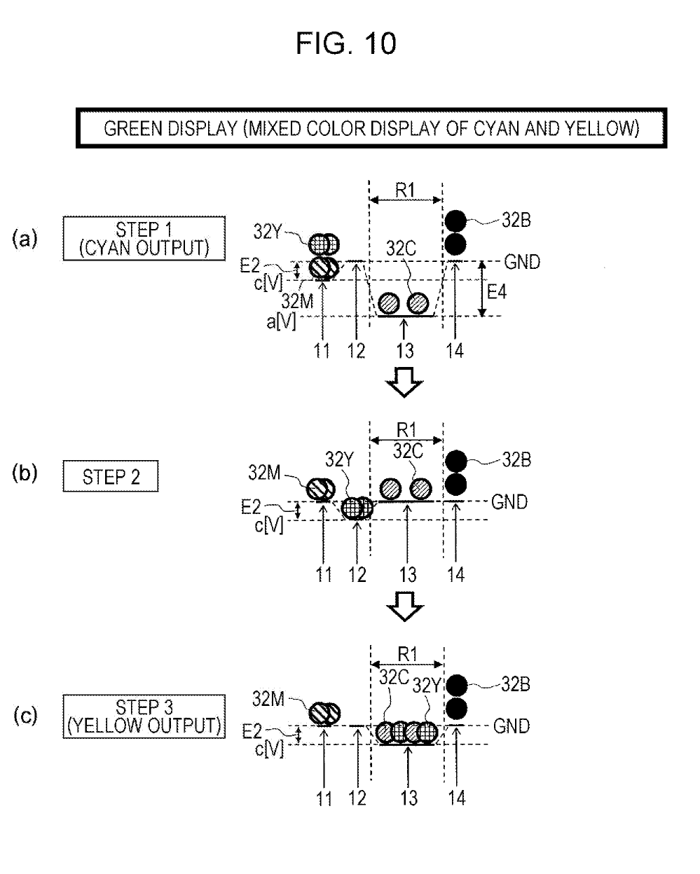

FIGS. 10(a) to (c) are views for explaining the display sequence of green display (that is, mixed color display of cyan and yellow). First, as illustrated in FIG. 10(a), the cyan particles 32C are caused to move to the opening region R1 (onto the third electrode 13) similarly to the display sequence of cyan display (step 1: cyan output)

Next, as illustrated in FIG. 10(b), each of the potentials of the first electrode 11 and the third electrode 13 is set to be the ground potential GND and the potential of the second electrode 12 is set to be c[V] (step 2). At this time, the potential gradient corresponding to the electric field intensity E2 is formed between. the first electrode 11 and the second electrode 12, so that the yellow particles 32Y that are on the first electrode 11 move onto the second electrode 12 (the magenta particles 32M stay on the first electrode 11).

Thereafter, as illustrated in FIG. 10(c), the potential of the second electrode 12 is set to be the ground potential GND and the potential of the third electrode 13 is set to be c[V] (step 3). At this time, the potential gradient corresponding to the electric field intensity E2 is formed between the second electrode 12 and the third electrode 13, so that the yellow particles 32Y that are on the second electrode 12 move to the opening region R1 (onto the third electrode 13) (yellow output). Therefore, green display subtractive color mixture of cyan and yellow is performed in this state.

### [Blue Display]

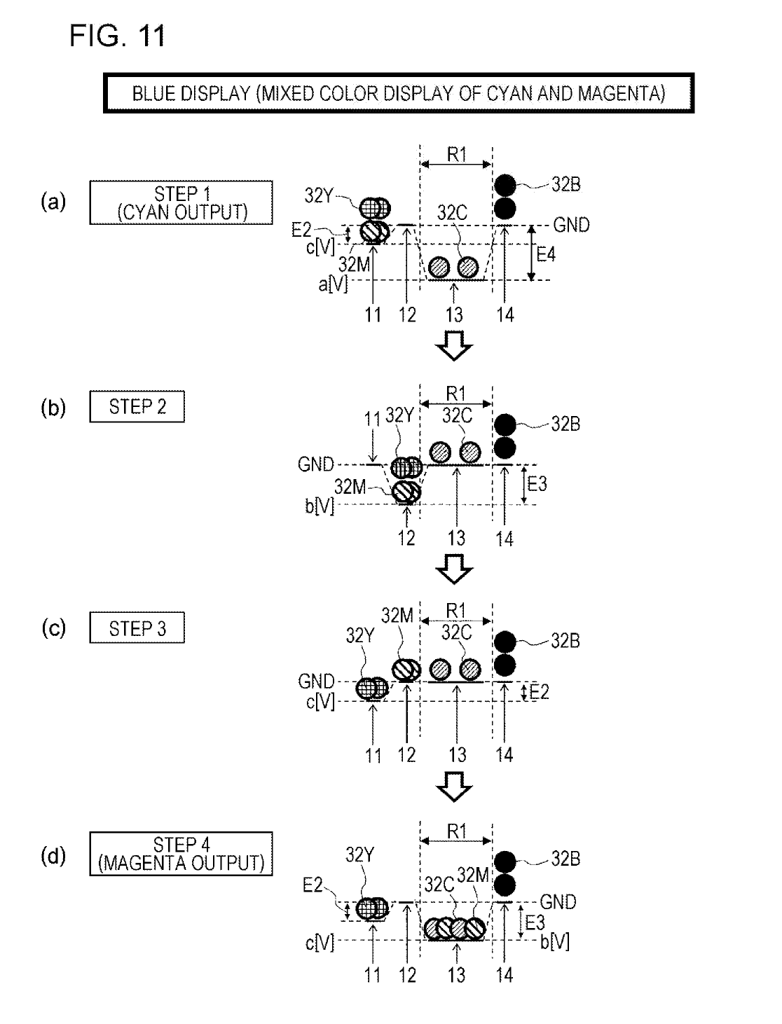

FIGS. 11(a) to (d) are views for explaining the display sequence of blue display (that is, mixed color display of cyan and magenta). First, as illustrated in FIG. 11(a), the cyan particles 32C are caused to move to the opening region R1 (onto the third electrode 13) similarly to the display sequence of cyan display (step 1: cyan output).

Next, as illustrated in FIG. 11(b), each of the potentials of the first electrode 11 and the third electrode 13 is set to be the ground potential GND and the potential of the second electrode 12 is set to be b[V] (step 2). At this time, the potential gradient corresponding to the electric field intensity E3 is formed between the first electrode 11 and the second electrode 12, so that the magenta particles 32M and the yellow particles 32Y that are on the first electrode 11 move onto the second electrode 12.

Subsequently, as illustrated in FIG. 11(c), the potential of the first electrode 11 is set to be c[V] and the potential of the second electrode 12 is set to be the ground potential GND (step 3). At this time, the potential gradient corresponding to the electric field intensity E2 is formed between the first electrode 11 and the second electrode 12, so that the yellow particles 32Y that are on the second electrode 12 move onto the first electrode 11.

Thereafter, as illustrated in FIG. 11(d), the potential of the third electrode 13 is set to be b[V] (step 4). At this time, the potential gradient corresponding to the electric field intensity E3 is formed between the second electrode 12 and the third electrode 13, so that the magenta particles 32M that are on the second electrode 12 move to the opening region R1 (onto the third electrode 13) (magenta output). Therefore, blue display by subtractive color mixture of cyan and magenta is performed in this state.

### [Red Display]

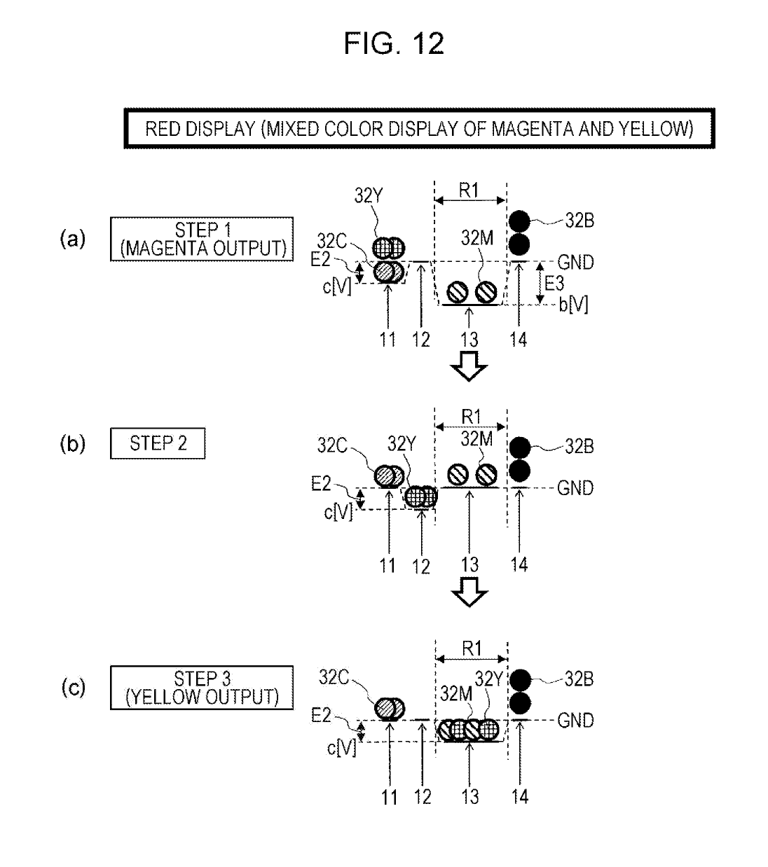

FIGS. 12(a) to (c) are views for explaining the display sequence of red display (that is, mixed color display of magenta and yellow). First, as illustrated in FIG. 12(a), the magenta particles 32M are caused to move to the opening region R1 similarly to the display sequence of magenta display (step 1: magenta output).

Next, as illustrated in FIG. 12(b), each of the potentials of the first electrode 11 and the third electrode 13 is set to be the ground potential GNU and the potential of the second electrode 12 is set to be c[V] (step 2). At this time, the potential gradient corresponding to the electric field intensity E2 is formed between the first electrode 11 and the second electrode 12, so that the yellow particles 32Y that are on the first electrode 11 move onto the second electrode 12 (the cyan particles 32C stay on the first electrode 11).

Thereafter, as illustrated in FIG. 12(c), the potential of the second electrode 12 is set to be the ground potential GND and the potential of the third electrode 13 is set to be c[V] (step 4). At this time, the potential gradient corresponding to the electric field intensity E2 is formed between the second electrode 12 and the third electrode 13, so that the yellow particles 32Y that are on the second electrode 12 move to the opening region R1 (onto the third electrode 13) (yellow output). Therefore, red display by subtractive color mixture of magenta and yellow is performed in this state.

### [Gradation Display]

Here, a display sequence of gradation display will be described by taking magenta and red as examples.

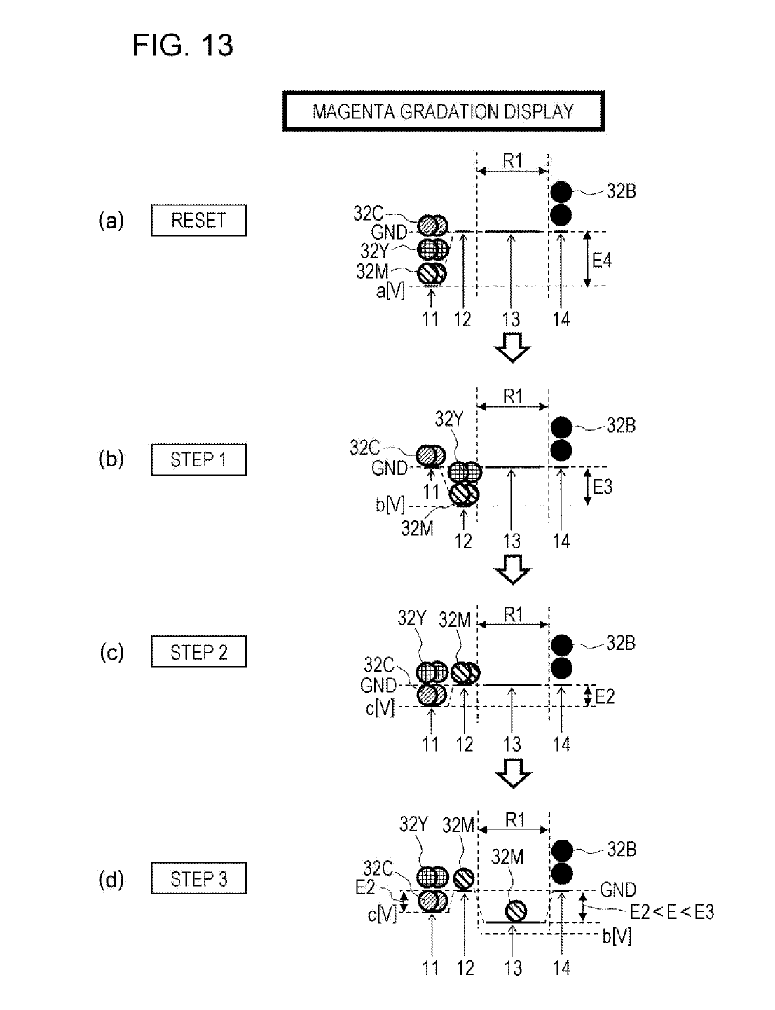

FIGS. 13(a) to (d) are views for explaining a display sequence of gradation. display of magenta. First, as illustrated in FIG. 13(a), the potentials are applied in the same manner as the state of the white display to the first electrode 11, the second electrode 12, the third electrode 13, and the fourth electrode 14 to perform reset.

Next, as illustrated in FIG. 13(b), the potential of the first electrode 11 is set to be the ground potential GND and the potential of the second electrode 12 is set to be b[V] (step 1). At this time, the potential gradient corresponding to the electric field intensity E3 is formed between the first electrode 11 and the second electrode 12, so that the magenta particles 32M and the yellow particles 32Y that are on the first electrode 11 move onto the second electrode 12 (the cyan particles 32C stay on the first electrode).

Subsequently, as illustrated in FIG. 13(c), the potential of the first electrode 11 is set to be c[V] and the potential of the second electrode 12 is set to be the ground potential GND (step 2). At this time, the potential gradient corresponding to the electric field intensity E2 is formed between the first electrode 11 and the second electrode 12, so that the yellow particles 32Y that are on the second electrode 12 move onto the first electrode 11 (the magenta particles 32M stay on the second electrode 12).

Thereafter, as illustrated in FIG. 13(d), the potential of the third electrode 13 is set to be higher than b[V] and lower than c[V] (step 3). At this time, a potential gradient corresponding to an electric field intensity E (E that satisfies a relation of E2<E<E3) that is greater than the electric field intensity E2 and smaller than the electric field intensity E3 is formed between the second electrode 12 and the third electrode 13, so that a part of the magenta particles 32M (desired amount of the magenta particles 32M) that are on the second electrode 12 moves to the opening region R1 (onto the third electrode 13). In this manner, it is possible to perform gradation display of magenta.

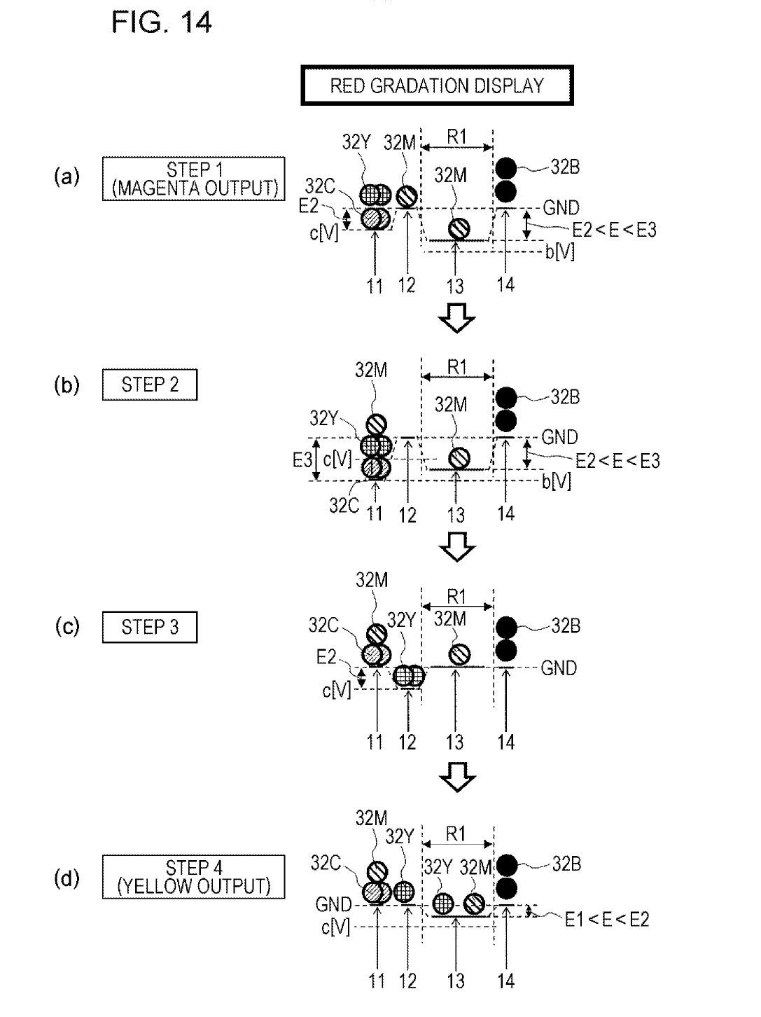

FIGS. 14(a) to (d) are views for explaining a display sequence of gradation display of red. First, as illustrated in FIG. 14(a), a part of the magenta particles 32M is caused to move to the opening region R1 similarly to the display sequence of gradation display of magenta (step 1: magenta output).

Next, as illustrated in FIG. 14(b), the potential of the first electrode 11 is set to be b[V] (step 2). At this time, the potential gradient corresponding to the electric field intensity E3 is formed between the first electrode 11 and the second electrode 12, so that the magenta particles 32M that are left on the second electrode 12 move onto the first electrode 11.

Subsequently, as illustrated in FIG. 14(c), each of the potentials of the first electrode 11 and the third electrode 13 is set to be the ground potential GND and the potential of the second electrode 12 is set to be c[V] (step 3). At this time, the potential gradient corresponding to the electric field intensity E2 is formed between the first electrode 11 and the second electrode 12, so that the yellow particles 32Y that are on the first electrode 11 move onto the second electrode 12 (the cyan particles 32C and the magenta particles 32M that are on the first electrode 11 stay).

Thereafter, as illustrated in FIG. 14(d), the potential of the second electrode 12 is set to be the ground potential GND and the potential of the third electrode 13 is set to be higher than c[V] and lower than the ground potential GND (step 4). At this time, a potential gradient corresponding to an electric field intensity E (E that satisfies a relation of E1<E<E2) that is smaller than the electric field intensity E2 and greater than the electric field intensity E1 is formed between the second electrode 12 and the third electrode 13, so that a part of the yellow particles 32Y (desired amount of the yellow particles 32Y) that are on the second electrode 12 moves to the opening region R1 (onto the third electrode 13). In this manner, it is possible to perform gradation display of red.

As described above, in the electrophoretic element 100 in the present embodiment, by controlling the potentials of the plurality of electrodes 11, 12, 13, and 14 that are included in the first substrate 10, it is possible to position, in the opening region R1, any type of electrophoretic particles 32 among a plurality of types of electrophoretic particles 32. Thus, it is possible to perform display (here, black display, cyan display, magenta display, or yellow display) in a state where only one type of electrophoretic particles 32 are positioned in the opening region R1, and also display (here, white display) in a state where none of the types of electrophoretic particles 32 is positioned in the opening region R1. Furthermore, in the electrophoretic element 100 in the present embodiment, it is also possible to perform display (for example, green display, blue display, or red display that have been exemplified) in a state where two or more types of electrophoretic particles 32 among the plurality of types of electrophoretic particles 32 are positioned in the opening region R1. That is, not juxtaposition color mixture (that is, color mixture by pixels Px) but subtractive color mixture (superposing colors) in one pixel Px is enabled.

Moreover, in the electrophoretic element 100, the column part 40a of the partition wall 40 covers a pair of electrodes (here, the first electrode 11 and the fourth electrode 14), which is composed of one electrode of one pixel Px of two pixels Px that are adjacent to each other via the column part 40a and one electrode of the other pixel Px. With such a configuration, it is possible to cut as influence of an electric field of an adjacent pixel within the partition wall 40, thus making it possible to suitably perform movement (that is, a display operation) of the electrophoretic particles 32.

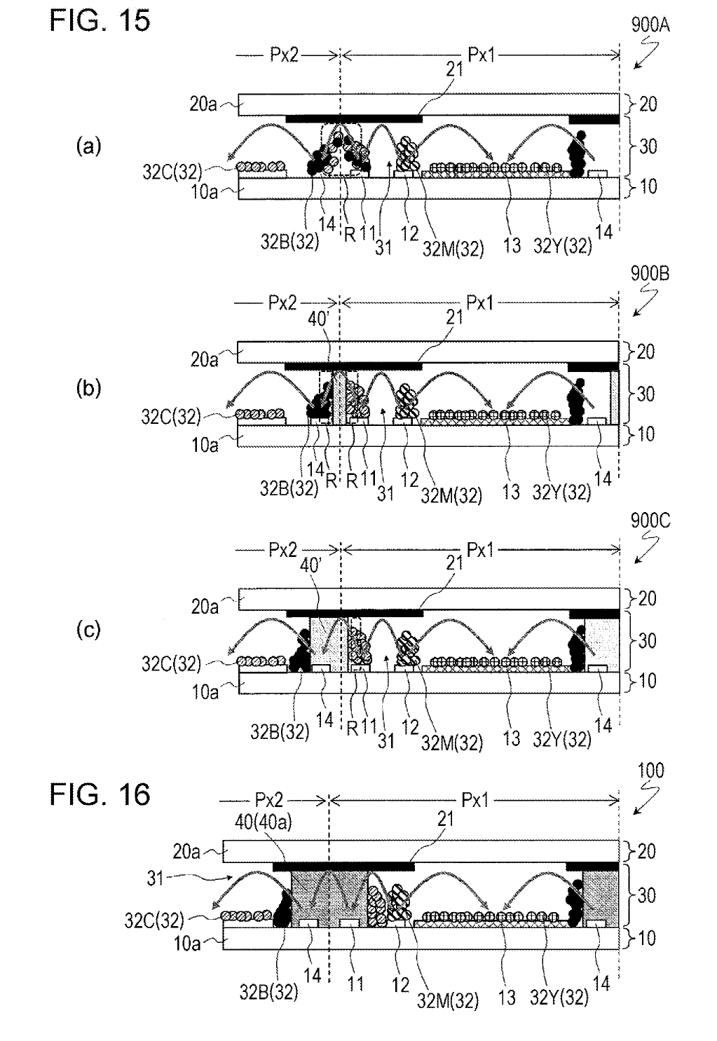

FIGS. 15(a), (b), and (c) respectively illustrate electrophoretic elements 900A, 900B, and 9000 of comparative examples 1, 2, and 3. A case where a potential V1 of the first electrode 11 is higher than a potential of the fourth electrode 14 (V4<V1), a potential V2 of the second electrode 12 is higher than. the potential of the first electrode 11 (V1<V2), and the potential V4 of the fourth electrode 14 is higher than a potential of the third electrode 13 (V3<V4) is taken. as an example here.

The electrophoretic element 900A of the comparative example 1 illustrated in FIG. 15(a) is different from the electrophoretic element 100 of the present embodiment in that the partition wall 40 is not included. As is clear from FIG. 15(a) (particularly, a region R surrounded by a dotted line in the figure), in a vicinity of a boundary between the first pixel Px1 and the second pixel Px2, the electrophoretic particles 32 are affected by a horizontal electric field generated by a potential difference between the first electrode 11 of the first pixel Px1 and the fourth electrode 14 of the second pixel Px2.

The electrophoretic element 900B of the comparative example 2 illustrated in FIG. 15(b) includes a partition wall 40′. However, the partition wall 40′ of the electrophoretic element 900B is different from the partition wall 40 of the electrophoretic element 100 of the present embodiment, and covers none of the four electrodes 11, 12, 13, and 14 of the first substrate 10. As is clear from FIG. 15(b) (particularly, the region R surrounded by a dotted line in the figure), in the vicinity of the boundary between the first pixel Px1 and the second pixel Px2, the electrophoretic particles 32 are affected by the horizontal electric field generated by the potential difference between the first electrode 11 of the first pixel Px1 and the fourth electrode 14 of the second pixel Px2.

The electrophoretic element 900C of the comparative example 2 illustrated in FIG. 15(c) includes the partition wall 40′. However, the partition wall 40′ of the electrophoretic element 900C covers the fourth electrode 14 of the first substrate 10 but does not cover the first electrode 11. As is clear from FIG. 15(c) (particularly, the region R surrounded by a dotted line in the figure), in the vicinity of the boundary between the first pixel Px1 and the second pixel Px2, the electrophoretic particles 32 are affected by the horizontal electric field generated by the potential difference between the first electrode 11 of the first pixel Px1 and the fourth electrode 14 of the second pixel Px2.

As above, crosstalk is caused in the electrophoretic elements 900A, 900B, and 900C of the comparative examples 1, 2, and 3.

On the contrary, in the electrophoretic element 100 of the present embodiment, since the first electrode 11 of the first pixel Px1 and the fourth electrode 14 of the second pixel Px2 are covered with the column part 40a of the partition wall 40 as illustrated in FIG. 16, the horizontal electric field generated by the potential difference between the first electrode 11 of the first pixel Px1 and the fourth electrode 14 of the second pixel Px2 does not extend outside the partition wall 40. Therefore, occurrence of crosstalk is prevented.

Note that, in the present specification, “covering” an electrode by the partition wall 40 means that the partition wall 40 overlaps with the electrode as viewed from the substrate surface normal direction of the first substrate 10. The partition wall 40 is not necessarily in contact with the electrode directly, and the insulating layer 19 may be formed on the electrode and the partition wall 40 may overlap with the electrode via the insulating layer 19 as in the present embodiment. Moreover, as described below, the partition wall 40 does not necessarily cover the entire electrode, and is only required to at least partially cover the electrode.

Moreover, although a case where four types of electrophoretic particles 32 are included has been exemplified in the present embodiment, the number of types of electrophoretic particles 32 is not limited to four. At least only two types of electrophoretic particles 32 are required to be included in the electrophoretic layer 30. The electrophoretic layer 30 may include two types of electrophoretic particles 32 which are charged with mutually the same polarity and threshold characteristics of which are mutually different, or may include two types of electrophoretic particles 32 which are charged with mutually different polarity.

When the electrophoretic layer 30 further includes, in addition to two types of electrophoretic particles 32 which are charged with mutually the same polarity and threshold characteristics of which are mutually different, another type of electrophoretic particles 32 which are charged with polarity different from that of the two types, control parameters of the electrophoretic particles 32 are increased, so that threshold control is facilitated.

In a case where four types of electrophoretic particles 32 are included, the electrophoretic layer 30 may include three types of electrophoretic particles 32 which are charged with mutually the same polarity and threshold characteristics of which are mutually different and another type of electrophoretic particles 32 which are charged with polarity different from that of the three types, or may include two types of electrophoretic particles 32 which are charged with mutually the same polarity and threshold characteristics of which are mutually different and another two types of electrophoretic particles 32 which are charged with polarity different from that of the two types and threshold characteristics of which are mutually different. With the latter configuration, a threshold voltage of the same polarity has two levels, so that material design of the electrophoretic particles 32 is facilitated compared with. that of the former configuration (in which a threshold voltage of one polarity has three levels).

Although a case where the first substrate 10 includes four (four types of) electrodes 11, 12, 13, and 14 in each pixel Px has been. exemplified in the present embodiment, as in Embodiment 2 described below, the first substrate 10 may include three (three types of) electrodes in each pixel Px, or the first substrate 10 may include five or more (five or more types of) electrodes in each pixel Px. In the case where the electrophoretic layer 30 includes four types of electrophoretic particles 32 as in the present embodiment, it is preferable that the first substrate 10 includes four or more (four or more types of) electrodes in each pixel Px.

### [Specific Configuration Example for Performing Active Matrix Drive]

The electrophoretic element (display device) 100 in the present embodiment is typically subjected to active matrix drive. A specific configuration example of the display device 100 of an active matrix drive type will be described below.

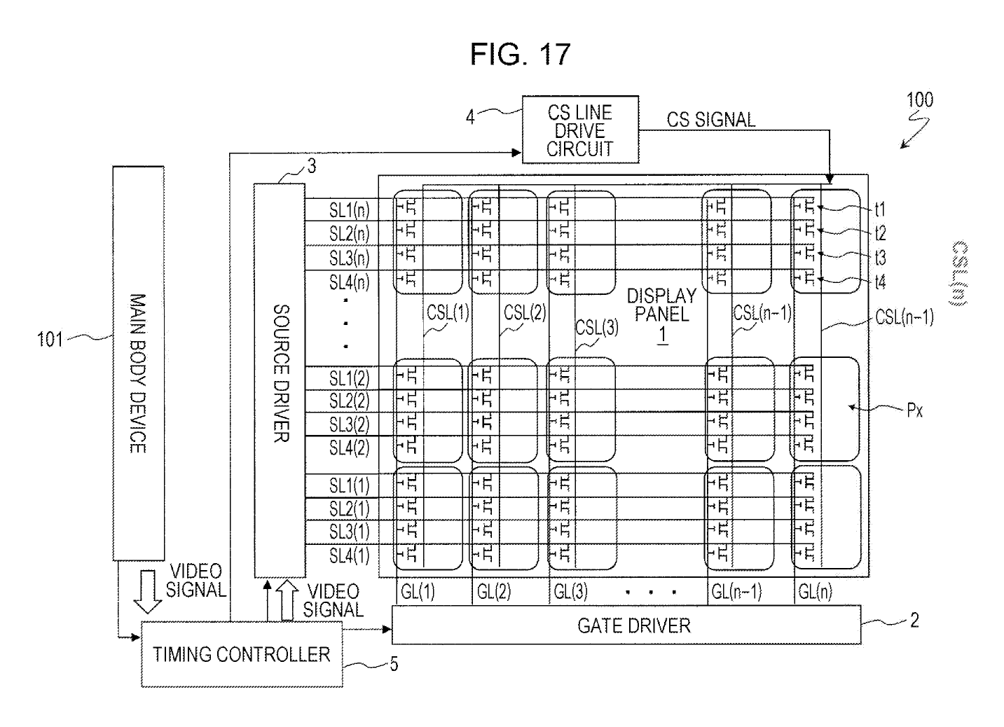

FIG. 17 illustrates the specific configuration example of the display device 100. In the example illustrated in FIG. 17, the display device 100 includes a main body device 101, a display panel 1, a gate driver (scanning line drive circuit) 2, and a source driver (signal line drive circuit) 3. Moreover, the display device 100 includes an auxiliary capacitance line drive circuit (CS line drive circuit) 4 and a timing controller 5.

The display panel 1 has four thin film transistors (TFT) t1, t2, t3, and t4 that are provided in each of the pixels Px. Moreover, in the display panel 1, a gate line GL is provided in each pixel row, four source lines SL1, SL2, SL3, and SL4 are provided in each pixel column, and an auxiliary capacitance line (CS line) CSL is provided in each pixel row. In FIG. 11, the gate line GL corresponding to an nth pixel row is denoted by GL(n), and the source lines SL1, SL2, SL3, and SL4 corresponding to an nth pixel column are respectively denoted by SL1(n), SL2(n), SL3(n), and SL4(n). Moreover, the CS line CSL corresponding to the nth row is denoted by CSL(n).

The gate driver 2 supplies a scanning signal voltage to each of the gate lines GL. The source driver 3 calculates, from a video signal input from the main body device 101 via the timing controller 5, a value of a voltage to be output to each of the pixels Px, and supplies a display signal voltage of the calculated value to each of the source lines SL1, SL2, SL3, and SL4.

The CS line drive circuit 4 outputs a CS signal to each of the CS lines CSL on the basis of a signal input from the timing controller 5.

On the basis of a clock signal, a horizontal synchronization signal, and a vertical synchronization signal that are input from the main body device 101, the timing controller 5 outputs, to the gate driver 2 and the source driver 3, a signal in accordance with which the gate driver 2 and the source driver 3 operate in synchronization. Specifically, the timing controller 5 outputs a gate start pulse signal, a gate clock signal, and a gate output enable signal to the gate driver 2 on the basis of the vertical synchronization signal. Moreover, the timing controller 5 outputs a source start pulse signal, a source latch strobe signal, and a source clock signal to the source driver 3 on the basis of the horizontal synchronization signal.

The gate driver 2 starts scanning of the display panel 1 upon reception of the gate start pulse signal from the timing controller 5, and sequentially applies an on-voltage to each of the gate lines GL in accordance with the gate clock signal that is a signal which shifts a selected state of the gate line GL. On the basis of the source start pulse signal received from the timing controller 5, the source driver 3 stores image data of each pixel, which is input, in a register in accordance with the source clock signal. After storing the image data, the source driver 3 writes the image data in each of the source lines SL1, SL2, SL3, and SL4 of the display panel 1 in accordance with a next source latch strobe signal. For example, an analog amplifier included in the source driver 3 is used for writing the image data.

The main body device 101 transmits the video signal and a video synchronization signal to the timing controller 5 in order to control display of the display panel 1.

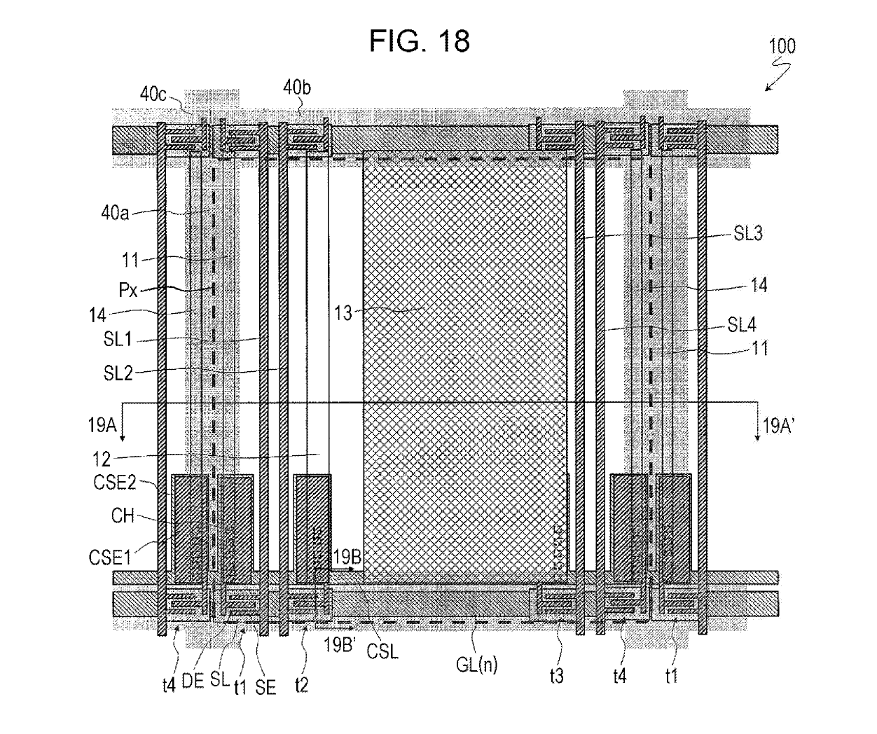

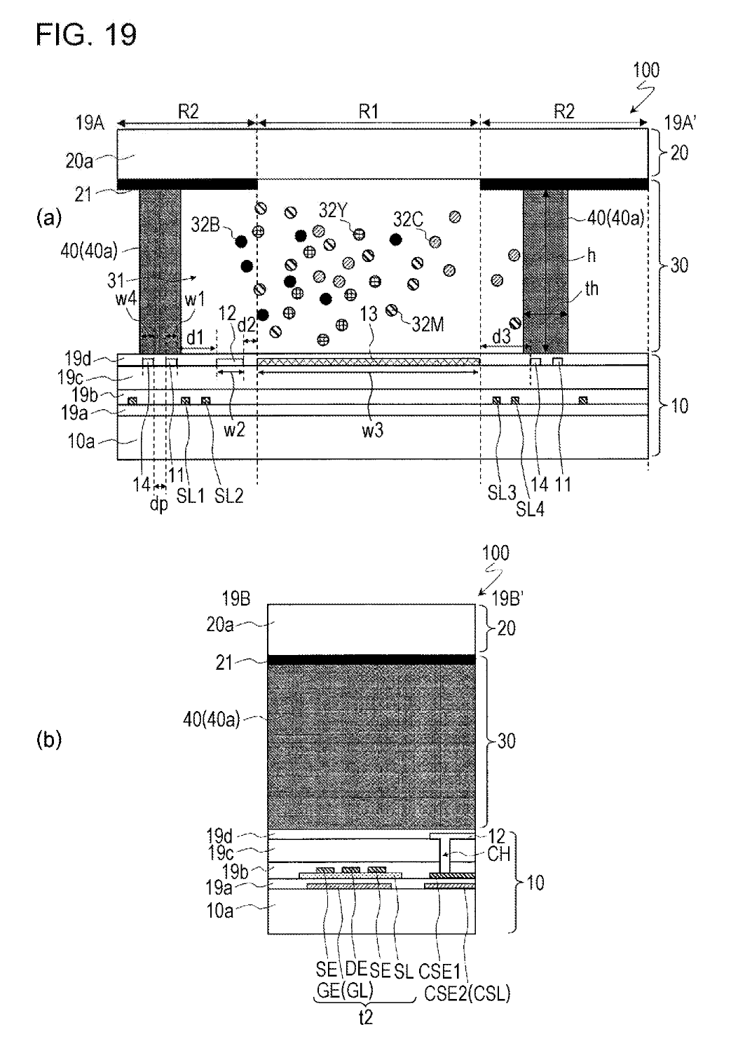

Subsequently, a more specific configuration example of the display device 100 will be described with reference to FIG. 18 and FIGS. 19(a) and (b). FIG. 18 is a plan view schematically illustrating the display device 100. FIGS. 19(a) and (b) are cross-sectional views taken along a 19A-19A′ line and a 19B-19B′ line in FIG. 18, respectively.

As illustrated in FIG. 18, four TFTs, specifically, a first TFT t1, a second TFT t2, a third TFT t3, and a fourth TFT t4 are provided in each of the pixels Px. Each of the first TFT t1, the second TFT t2, the third TFT t3, and the fourth TFT t4 includes a gate electrode GE, a source electrode SE, a drain electrode DE, and a semiconductor layer SL as illustrated in FIG. 18 and FIG. 19(b).

The gate electrodes GE of the first TFT t1, the second TFT t2, the third TFT t3, and the fourth TFT t4 are electrically connected to the common crate line GL. The source electrodes SE or the first TFT t1, the second TFT t2, the third TFT t3, and the fourth TFT t4 are electrically connected to the first source line SL1, the second source line SL2, the third source line SL3, and the fourth source line SL4, respectively. The drain electrodes DE of the first TFT t1, the second TFT t2, the third TFT t3, and the fourth TFT t4 are electrically connected to the first electrode 11, the second electrode 12, the third electrode 13, and the fourth electrode 14, respectively.

An auxiliary capacitance is constituted by an auxiliary capacitance electrode (CS electrode) CSE1 that is extended from the drain electrode DE, an auxiliary capacitance counter electrode (CS counter electrode) CSE2 that is extended from the CS line CSL, and an insulating layer (gate insulating layer described below) 19a that is positioned therebetween.

The gate line GL, the gate electrode GE, the CS line CSL, and the CS counter electrode CSE2 are formed on a surface on a side of the electrophoretic layer 30 in the transparent substrate (for example, a glass substrate) 10a included in the first substrate 10. The gate line GL, the gate electrode GE, the CS line CSL, and the CS counter electrode CSE2 are able to be formed by patterning the same metal film. The gate insulating layer (first insulating layer) 19a is formed so as to cover the gate line GL, the gate electrode GE, and the like.

The semiconductor layer SL that is island-shaped is formed on the gate insulating layer 19a. Various publicly known semiconductor materials are able to be used as a material of the semiconductor layer SL, and amorphous silicon, polycrystalline silicon, continuous grain silicon (CGS), or the like is able to be used, for example.

Moreover, the semiconductor layer SL may be an oxide semiconductor layer formed of an oxide semiconductor. The oxide semiconductor layer includes, for example, an In-Ga-Zn-O based semiconductor. Here, the In-Ga-Zn-O based semiconductor is a ternary oxide of In (indium), Ga (gallium), and Zn (zinc). A ratio (composition ratio) of In, Ga, and Zn is not limited in particular, and includes, for example, In:Ga:Zn=2:2:1, In:Ga:Zn=1:1:1, In:Ga:Zn=1:1:2, or the like. The In-Ga-Zn-O based semiconductor may be an amorphous or crystalline substance. As the In—Ga—Zn—O based semiconductor of the crystalline substance, one whose c axis is oriented substantially in a vertical direction with respect to a layer surface is preferable. A crystal structure of such an In—Ga—Z—O based semiconductor is disclosed in Japanese Unexamined Patent Application. Publication No. 2012-134475, for example. For reference, the entire contents of the disclosure of Japanese Unexamined Patent Application Publication No. 2012-134475 are invoked in the present specification. A TFT having an In—Ga—Zn—O based semiconductor layer has high mobility (more than 20 times of that of an a-Si TFT) and a low leak current (less than one-hundredth of that of the a-Si TFT). Accordingly, when the oxide semiconductor layer formed of the In—Ga—Zn—O based semiconductor is used as the semiconductor layer, an amount of off-leak is small, so that it is possible to achieve further reduction in power consumption.

Note that, the oxide semiconductor layer is not limited to the In—Ga—Zn—O based semiconductor layer. The oxide semiconductor layer may include, for example, a Zn—O based semiconductor (ZnO), an In—Zn—O based semiconductor (IZO), a Zn—Ti—O. based semiconductor (ZTO), a Cd—Ge—O based semiconductor, a Cd—Pb—O based semiconductor, an In—Sn—Zn—O based semiconductor (for example, In₂O₃—SnO₂—ZnO), an In—Ga—Sn—O based semiconductor, or the like.

The source electrode SE and the drain electrode DE are formed so as to overlap with the semiconductor layer SL. Moreover, the source lines SL1, SL2, SL3, and SL4 and the CS electrode CSE1 are also formed on the gate insulating layer 19a. The source electrode SE, the drain electrode DE, the source lines SL1, SL2, SL3, and SL4, and the CS electrode CSE1 are able to be formed by patterning the same metal film. An interlayer insulating layer (second insulating layer) 19b is formed so as to cover the source electrode SE, the drain electrode DE, and the like.

On the interlayer insulating layer 19b, a flattening film (third insulating layer) 19c is formed. A material of the flattening film 19c is, for example, photosensitive acrylic resin.

The first electrode 11, the second electrode 12, the third electrode 13, and the fourth electrode 14 are formed. on the flattening film 19c. The third electrode 13 that is the reflection electrode includes a layer formed of a metal material (for example, aluminum) having high reflectivity. The third electrode 13 may have a multilayer structure that includes a plurality of layers formed of different conductive materials. For example, the third electrode 13 has a multilayer structure in which a titanium layer, an aluminum layer, and an ITO layer are laminated in this order from a side of the transparent substrate 10a. The ITO layer in this configuration has a function of preventing corrosion of the aluminum layer.

Since the third electrode 13 is the reflection electrode, it is possible to arrange a line, a TFT, an auxiliary capacitance, and the like under the reflection electrode (which functions as a light reflecting layer), so that a reflection aperture ratio is improved. The third electrode 13 may be a mirror reflection electrode that mirror-reflects light or a diffuse reflection electrode that diffuses and reflects light. In a case where the mirror reflection electrode is used as the third electrode 13, it is preferable that a light diffusing layer (for example, a light diffusing film) that diffuses light is provided closer to the front surface side compared with the electrophoretic layer 30. In a case where the diffuse reflection electrode is used as the third electrode 13, by forming an uneven shape on a surface of the insulating layer 19c, which is positioned directly under the third electrode 13, it is possible to give an uneven shape (which reflects the uneven shape of the surface of the insulating layer 19c) on a surface of the third electrode 13 and cause the third electrode 13 to function as the diffuse reflection electrode.

The first electrode 11, the second electrode 12, and the fourth electrode 14 may be reflection electrodes that have the same configuration as that of the third electrode 13, or may be transparent electrodes each of which is formed of a transparent conductive material. A contact hole CH is formed in the interlayer insulating layer 19b and the flattening film 19c, and the first electrode 11, the second electrode 12, the third electrode 13, and the fourth electrode 14 are connected to the CS electrode CSE1 in the contact hole CH and electrically connected to the drain electrode DE via the CS electrode CSE1.

Ah insulating layer (fourth insulating layer) 19d is formed so as to cover the first electrode 11, the second electrode 12, the third electrode 13, and the fourth electrode 14. The insulating layer 19d is an SiN layer or an SiO₂ layer each of which has a thickness of 100 nm, for example. Note that, the insulating layer 19d may be omitted. When the insulating layer 19d is provided, it is possible to prevent sticking of the electrophoretic particles 32 to the first substrate 10 or leakage between electrodes.

On a surface of the transparent substrate (for example, a glass substrate) 20a included in the second substrate 20, which is on the side of the electrophoretic layer 30, the light shielding layer 21 is formed so as to be positioned in the light shielding region R2. Examples of a material of the light shielding layer 21 include black acrylic resin and a metal material having low reflectivity. The first electrode 11, the second electrode 12, the third electrode 13, and the fourth electrode 14 of the first substrate 10 are arranged so as to overlap with the light shielding layer (that is, so as to be within the region R2).

Between the first substrate 10 and the second substrate 20, the partition wall 40 that partitions the electrophoretic layer 30 into individual pixels Px is provided. The partition wall 40 is formed of a dielectric material. Photoresist is able to be suitably used as the dielectric material that is the material of the partition wall 40, but there is no limitation thereto. As photoresist, for example, chemically amplified epoxy-based negative resist (SU-8 manufactured by Nippon Kayaku Co., Ltd.) or the like is able to be used. A height h of the partition wall 40 is, for example, 10 μm to 60 μm, and a width th of the partition wall 40 is, for example, 10 μm to 60 μm.

The dispersion medium 31 is an insulating colorless transparent liquid. As the dispersion medium 31, for example, isoparaffin, toluene, xylene, normal paraffin each of which is a hydrocarbon-based solvent, or silicone oil is able to be used.

As the electrophoretic particles 32 (the cyan particles 32C, the magenta particles 32M, the yellow particles 32Y, and the black particles 32B), pigment particles having a desired color or resin particles that includes pigment or dye having a desired color are able to be used. As the pigment or the dye, for example, general pigment or dye used for printing ink or color toner is able to be used. It is possible to determine the threshold characteristics (applied voltage necessary for movement) of the electrophoretic particles 32 by adjusting a charge amount, a particle diameter, a shape or a material of a particle surface, or the like. For example, it is possible to make the threshold characteristics of a plurality of types of electrophoretic particles 32 mutually different by a method disclosed in Japanese Patent No. 5333045. For reference, the entire contents of the disclosure of Japanese Patent No. 5333045 are invoked in the present specification.

An average particle diameter (in this case, a volume average diameter) of the electrophoretic particles 32 is typically not less than 0.01 μm and not more than 10 μm, and preferably not less than 0.03 μm and not more than 3 μm. When the volume average diameter of the electrophoretic particles 32 is less than 0.03 μm, there is a possibility that the charge amount of the electrophoretic particles 32 becomes small and moving speed becomes low. Moreover, when the volume average diameter of the electrophoretic particles 32 is not less than 3 μm, there is a possibility that, even though the moving speed is adequate, precipitation due to their own weights or deterioration of memory properties is caused.

### [Preferable Configuration of Electrode]

In the example illustrated in FIG. 18, the first electrode 11 and the fourth electrode 14 (pair of electrodes that are covered with the column part 40a of the partition wall 40) are arranged so as to extend approximately in parallel to each other. By adopting such a configuration, it is possible to reduce the width th of the partition wall 40 (column part 40a).

Moreover, in the example illustrated in FIG. 18, the column part 40a of the partition wall 40 has a shape (more specifically, an approximately rectangular shape) including two sides that are approximately parallel in the column direction as viewed from the substrate surface normal direction of the first substrate 10. Each of the first electrode 11 and the fourth electrode 14 (pair of electrodes that are covered with the column part 40a of the partition wall 40) is arranged in a vicinity of each of the above-described two sides. Moreover, a part of each of the first electrode 11 and the fourth electrode 14 (each end part in the column direction) is covered with the connection part 40c of the partition wall 40. By adopting such a configuration, it is possible to reduce the width th of the partition wall 40 (column part 40a) and efficiently generate a horizontal electric field within the pixel Px.

A distance dp (refer to FIG. 19(a)) between the pair of electrodes (the first electrode 11 and the fourth electrode 14) that are covered with the column part 40a of the partition wall 40 is preferably equal to or shorter than a distance between any two electrodes, which are adjacent to each other, among the four electrodes 11, 12, 13, and 14 of each of the pixels Px. That is, the distance dp is preferably equal to or shorter than a distance d1 between the first electrode 11 and the second electrode 12, equal to or shorter than a distance d2 between the second electrode 12 and the third electrode 13, and equal to or shorter than a distance d3 between the third electrode 13 and the fourth electrode 14. In the electrophoretic element 100 of the present embodiment, a horizontal electric field generated between the pair of electrodes 11 and 14 that are covered with the partition wall 40 is not used for display. Therefore, as described above, by reducing the distance dp between the pair of electrodes 11 and 14, which are covered with the partition wall 40, as much as possible (so as to be equal to or shorter than a distance between adjacent electrodes in the pixel Px), it is possible to reduce the width th of the partition wall 40 (column part 40a) and improve an opening rate. Specifically, the distance dp is preferably not less than 2 μm and not more than 5 μm.

It is preferable that each of a width w1 of the first electrode 11 and a width w4 of the fourth electrode 14 is equal to or shorter than each of a width w2 of the second electrode 12 and a width w3 of the third electrode 13. That is, it is preferable that the widths of the electrodes, which are covered with the column part 40a of the partition wall 40, among the four electrodes 11, 12, 13, and 14 of each of the pixels Px are equal to or shorter than the widths of the electrodes that are not covered with the column part 40a. By adopting such a configuration to thereby reduce the widths of the electrodes in the partition wall 40 as much as possible, it is possible to reduce the width th of the partition wall 40 (column part 40a) and improve the opening rate. Specifically, it is preferable that each of the widths of the electrodes (in this case, each of the width w1 of the first electrode 11 and the width w4 of the fourth electrode 14) that are covered with the column part 40a of the partition wall 40 is not less than 2 μm and not more than 5 μm.

### [Preferable Configuration of Light Shielding Layer]

It is preferable that, as illustrated in FIG. 1 and the like, the light shielding layer 21 includes the region (second light shielding region) 21b, which extends from the first light shielding region 21a in the row direction, in addition to the region (first shielding region) 21a overlapping with the column part 40a of the partition wall 40. In the electrophoretic element 100 of the present embodiment, depending on a display state, the electrophoretic particles 32 are accumulated on a side surface of the partition wall 40 (column part 40a) as illustrated in FIG. 16. When the light shielding layer 21 includes the second light shielding region 21b, it is possible to shield the electrophoretic element 32 accumulated on the side surface of the partition wall 40 (column part 40a) from light.

### [Light Reflecting Layer]

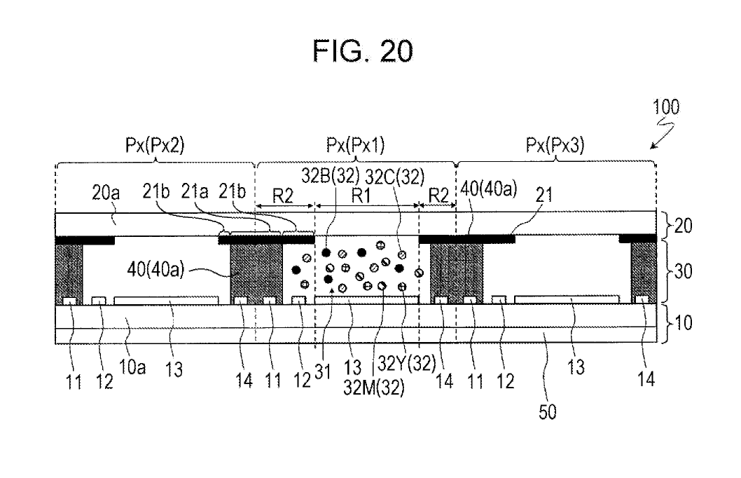

Although the configuration in which the third electrode 13 is the reflection electrode has been exemplified in the description above, the electrophoretic element 40 of the present embodiment is not limited to the configuration. As illustrated in FIG. 20, in the opening region R1, a light reflecting layer 50 that is white may be provided closer to a rear surface than the electrophoretic layer 30 and a transparent electrode may be used as the third electrode 13. Although a configuration in which the light reflecting layer 50 is arranged closer to the rear surface of the transparent substrate 10a is exemplified in FIG. 20, the light reflecting layer 50 may be provided closer to a front surface of the transparent substrate 10a (that is, between the transparent substrate 10a and the electrophoretic layer 30). Moreover, the light reflecting layer 50 may be a diffuse reflecting layer that diffuses and reflects light, or a mirror reflecting layer that mirror-reflects light. In a case where the mirror reflecting layer is used as the light reflecting layer 50, it is preferable that the mirror reflecting layer is used in combination with a light diffusing layer (forward diffusing layer) provided closer to the front surface than the electrophoretic layer 30

As the light reflecting layer 50 that is white, a diffuse reflecting film (for example, an aluminum deposited film or a silver deposited film) for a reflective liquid crystal display device is able to be used. Moreover, instead of the diffuse reflecting film, a combination of a diffusing film and a mirror reflecting film (for example, an aluminum deposited film or a silver deposited film) may be used. Furthermore, it is also possible to use a white reflecting plate for a backlight of a liquid crystal display device.

Note that, a color of the light reflecting layer 50 is not limited to white that is exemplified. The light reflecting layer 50 may have a black color or a specific chromatic color (for example, cyan, magenta, or yellow). Moreover, instead of the light reflecting layer 50, a light absorbing layer may be provided.

### [Example of Pixel Pitch, Electrode Size, and the Like]

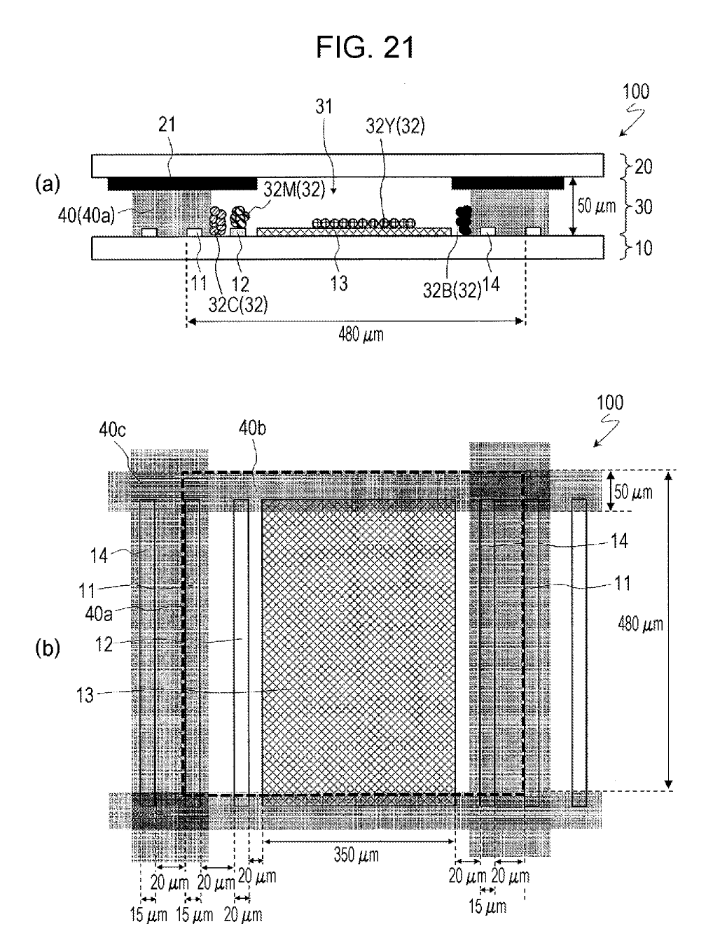

FIGS. 21(a) and (b) are views illustrating an example of pixel pitch and an electrode size of a case where resolution is 52 ppi (case where a diagonal length is 42 inches, a pixel number in a horizontal direction is 1920, and a pixel number in a vertical direction is 1080).

In the example illustrated in FIGS. 21(a) and (b), the pixel pitch in the horizontal direction is 480 μm and the pixel pitch in the vertical direction is 480 μm. A thickness (cell gap) of the electrophoretic layer 30 is 50 μm. The width of the first electrode 11 is 15 μm and the width of the second electrode 12 is 20 μm. The width of the third electrode 13 is 350 μm and the width of the fourth electrode 14 is 15 μm. The distance between the first electrode 11 and the second electrode 12 is 20 μm and the distance between the second electrode 12 and the third electrode 13 is 20 μm. The distance between the third electrode 13 and the fourth electrode 14 is 20 μm. A distance between the fourth electrode 14 and the first electrode 11 that are covered with the partition wall 40 (column part 40a) is 20 μm. The width of the column part 40a of the partition wall 40 is 70 μm and a width of the row part 40b is 50 μm.

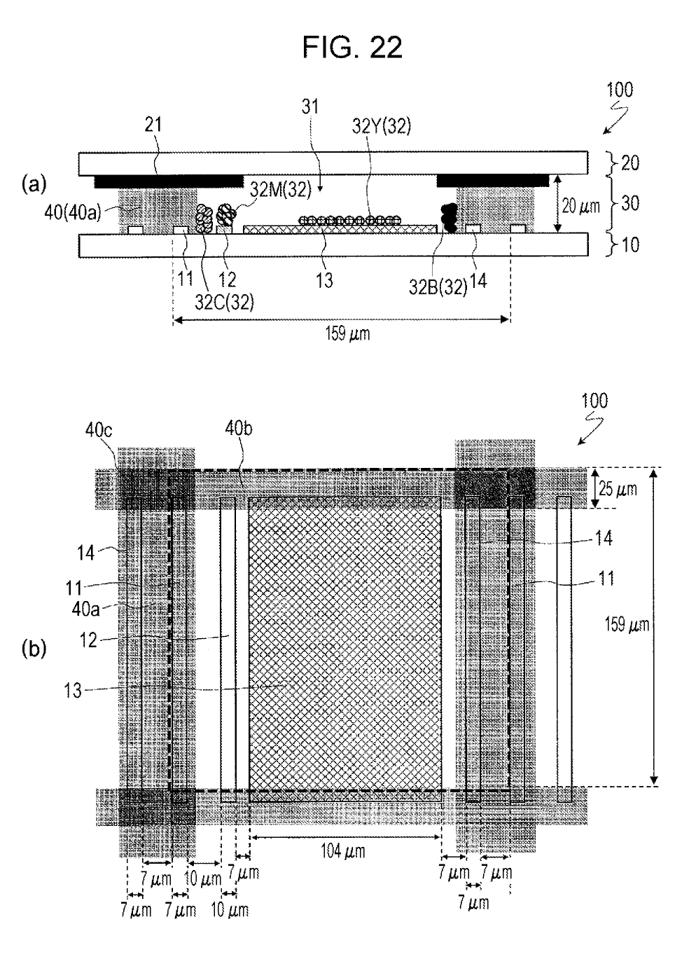

FIGS. 22(a) and (b) are views illustrating an example of a pixel pitch and an electrode size of a case where resolution is 160 ppi (case where the diagonal length is 6.3 inches, the pixel number in the horizontal direction is 800, and the pixel number in the vertical direction is 600).

In the example illustrated in FIGS. 22(a) and (b), the pixel pitch in the horizontal direction is 159 μm and the pixel pitch in the vertical direction is 159 μm. The thickness (cell gap) of the electrophoretic layer 30 is 20 μm. The width of the first electrode 11 is 7 μm and the width of the second electrode 12 is 10 μm. The width of the third electrode 13 is 104 μm and the width of the fourth electrode 14 is 7 μm. The distance between the first electrode 11 and the second electrode 12 is 10 μm and the distance between the second electrode 12 and the third electrode 13 is 7 μm. The distance between the third electrode 13 and the fourth electrode 14 is 7 μm. The distance between the fourth electrode 14 and the first electrode 11 that are covered with the partition wall 40 (column part 40a) is 7 μm. The width of the column part 40a of the partition wall 40 is 31 μm and the width of the row part 40b is 25 μm.

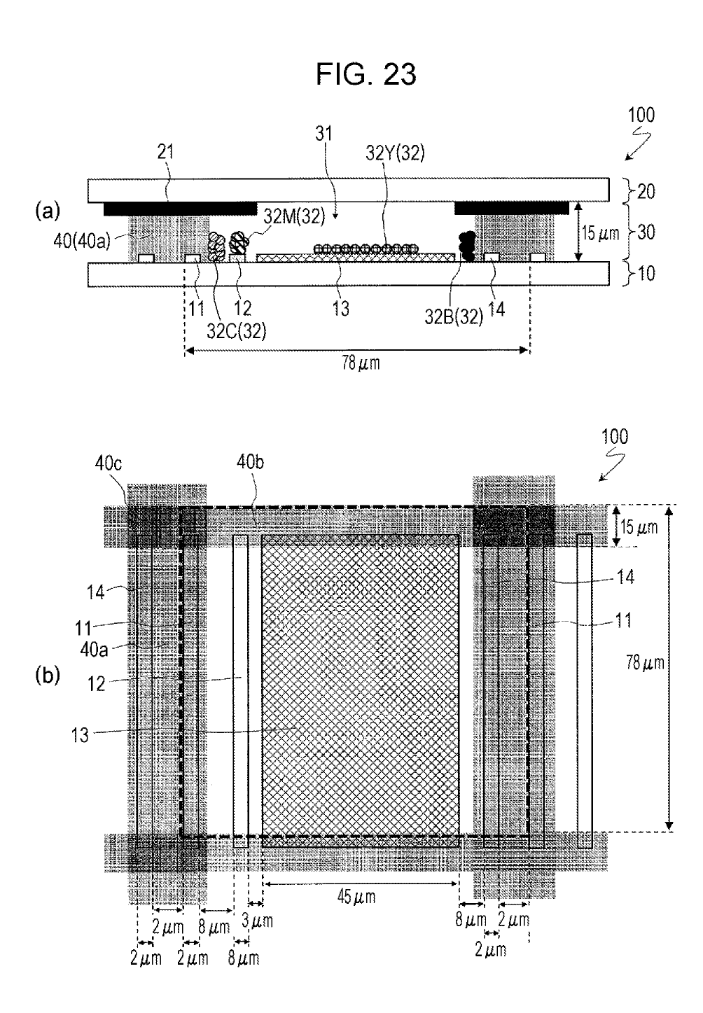

FIGS. 23(a) and (b) are views illustrating an example of a pixel pitch and an electrode size of a case where resolution is 326 ppi (case where the diagonal length is 4.7 inches, the pixel number in the horizontal direction is 1334, and the pixel number in the vertical direction is 750).

In the example illustrated in FIGS. 23(a) and (b), the pixel pitch in the horizontal direction is 78 μm and the pixel pitch in the vertical direction is 78 μm. The thickness (cell gap) of the electrophoretic layer 30 is 15 μm. The width of the first electrode 11 is 2 μm and the width of the second electrode 12 is 8 μm. The width of the third electrode 13 is 45 μm and the width of the fourth electrode 14 is 2 μm. The distance between the first electrode 11 and the second electrode 12 is 8 μm and the distance between the second electrode 12 and the third electrode 13 is 3 μm. The distance between the third electrode 13 and the fourth electrode 14 is 8 μm. The distance between the fourth electrode 14 and the first electrode 11 that are covered with the partition wall 40 (column part 40a) is 2 μm. The width of the column part 40a of the partition wall 40 is 10 μm and the width of the row part 40b is 15 μm.

### [Another Example of Electrode Arrangement]

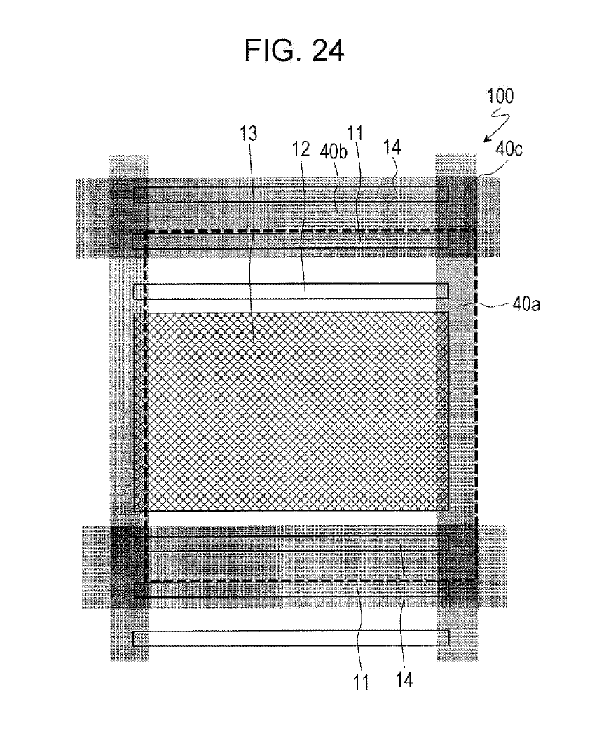

Although the configuration in which the first electrode 11 and the fourth electrode 14 extend along the column direction and the column part 40a of the partition wall 40 covers the first electrode 11 and the fourth electrode 14 has been described above as an example, a configuration illustrated in FIG. 24 may be adopted.

In the configuration illustrated in FIG. 24, the first electrode 11 and the fourth electrode 14 extend along the row direction and the first electrode 11 and the fourth electrode 14 are covered with the row part 40b of the partition wall 40. Also in a case where such a configuration is adopted, it is possible to obtain a similar effect.

### Embodiment 2

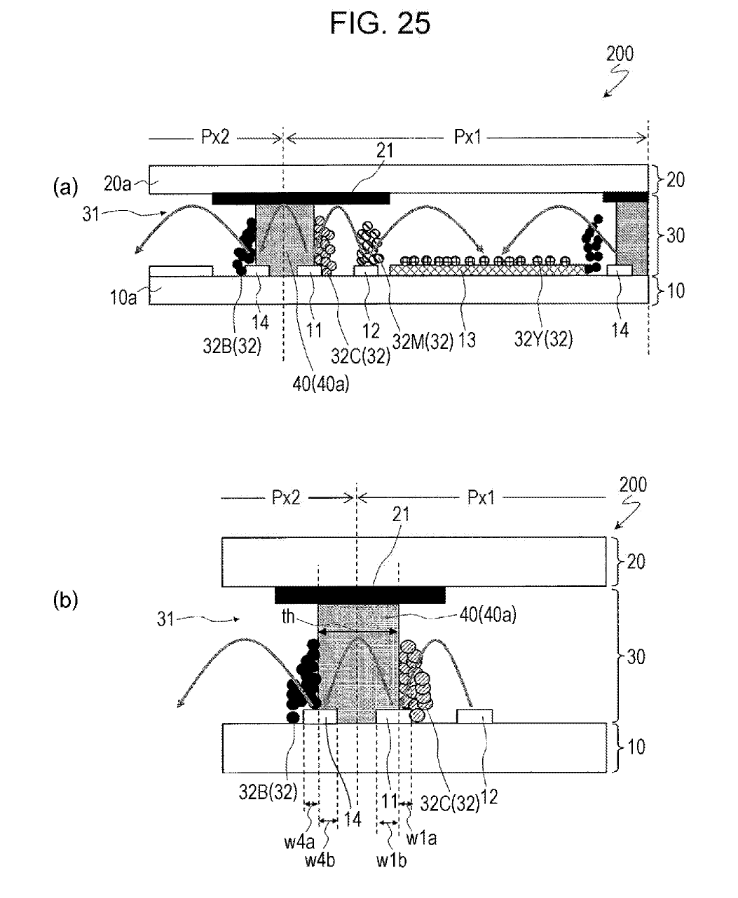

FIGS. 25(a) and (b) illustrate an electrophoretic element (display device) 200 in the present embodiment. FIG. 25(a) is a cross-sectional view schematically illustrating a certain pixel (first pixel) Px1 of the electrophoretic element 200 and a part of a pixel (second pixel) Px2 that is adjacent thereto, and FIG. 25(b) is an enlarged view of a vicinity of a boundary of the first pixel Px1 and the second pixel Px.

In the electrophoretic element 200 of the present embodiment, the partition wall 40 partially covers each of the first electrode 11 and the fourth electrode 14. That is, each of the first electrode 11 and the fourth electrode 14 has a part that is not covered with the column part 40a of the partition wall 40.

When each of the first electrode 11 and the fourth electrode 14 is at least partially covered with the column part 40a of the partition wall 40, it is possible to reduce an influence of a potential on the electrophoretic particles 32 from an adjacent pixel.

It is preferable that a width w1a of the part of the first electrode 11, which is not covered with the column part 40a of the partition wall 40, is equal to or shorter than a width w1b of the part which is covered with the column part 40a of the partition wall 40 (a relation of w1a w1b is satisfied). Moreover, it is preferable that a width w4a of the part of the fourth electrode 14, which is not covered with the column part 40a of the partition wall 40, is equal to or shorter than a width w4b of the part which is covered with the column part 40a of the partition wall 40 (a relation of w4a≤w4b is satisfied). Since a horizontal electric field generated between the first electrode 11 and the fourth electrode 14 extends up to a vicinity of the center of each of the first electrode 11 and the fourth electrode 14 in a width direction, when the relations of w1a≤w1b and w4a≤w4b are satisfied, it is possible to more reliably prevent occurrence of crosstalk. That is, by reducing the width th of the column part 40a of the partition wall 40 as much as possible within a range that satisfies the relations of w1a≤w1b and w4a≤w4b, it is possible to achieve further improvement of the opening rate.

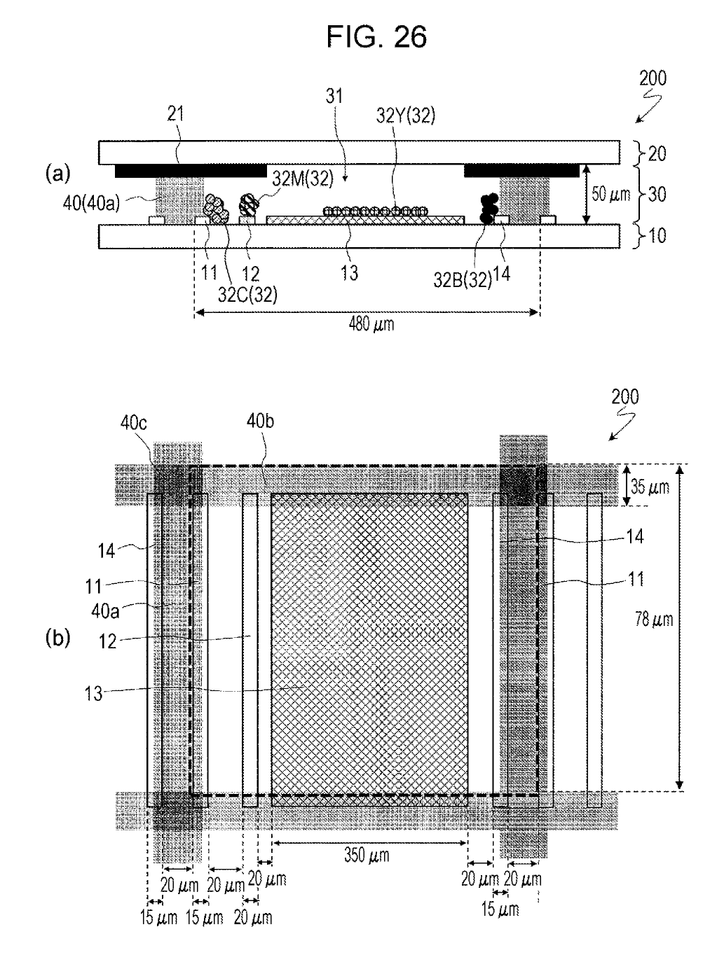

FIGS. 26(a) and (b) are views illustrating an example of a pixel pitch and an electrode size of the case where resolution is 52 ppi (case where the diagonal length is 42 inches, the pixel number in the horizontal direction is 1920, and the pixel number in the vertical direction is 1080).

In the example illustrated in FIGS. 26(a) and (b), the pixel pitch in the horizontal direction is 480 μm and the pixel pitch in the vertical direction is 480 μm. The thickness (cell gap) of the electrophoretic layer 30 is 50 μm. The width of the first electrode 11 is 15 μm and the width of the second electrode 12 is 20 μm. The width of the third electrode 13 is 350 μm and the width of the fourth electrode 14 is 15 μm. The distance between the first electrode 11 and the second electrode 12 is 20 μm and the distance between the second electrode 12 and the third

electrode 13 is 20 μm. The distance between the third electrode 13 and the fourth electrode 14 is 20 μm. The distance between the fourth electrode 14 and the first electrode 11 that are covered with the partition wall 40 (column part 40a) is 20 μm. The width of the column part 40a of the partition wall 40 is 30 μm and the width of the row part 40b is 35 μm.

### Embodiment 3

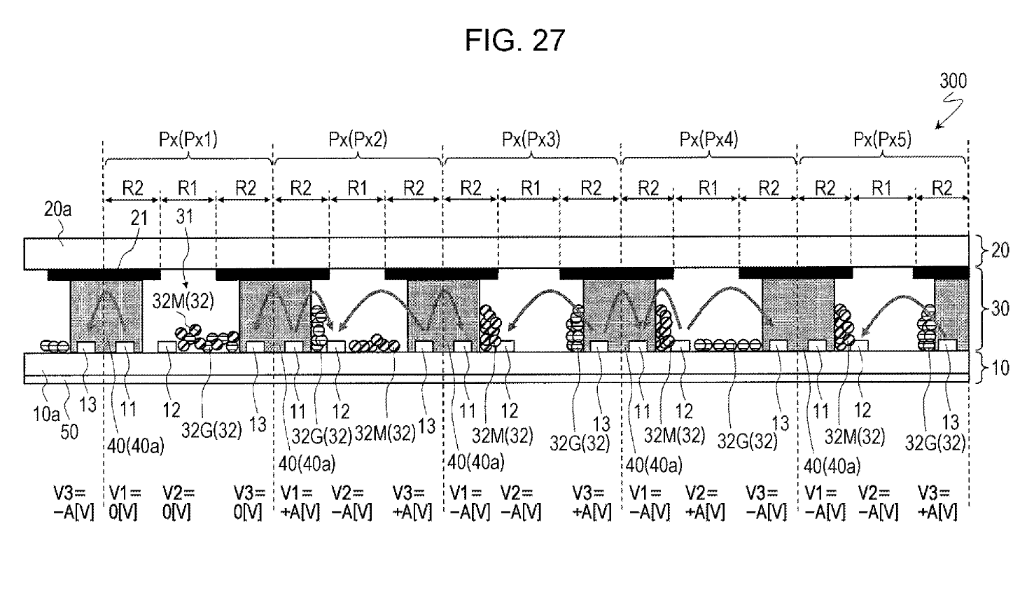

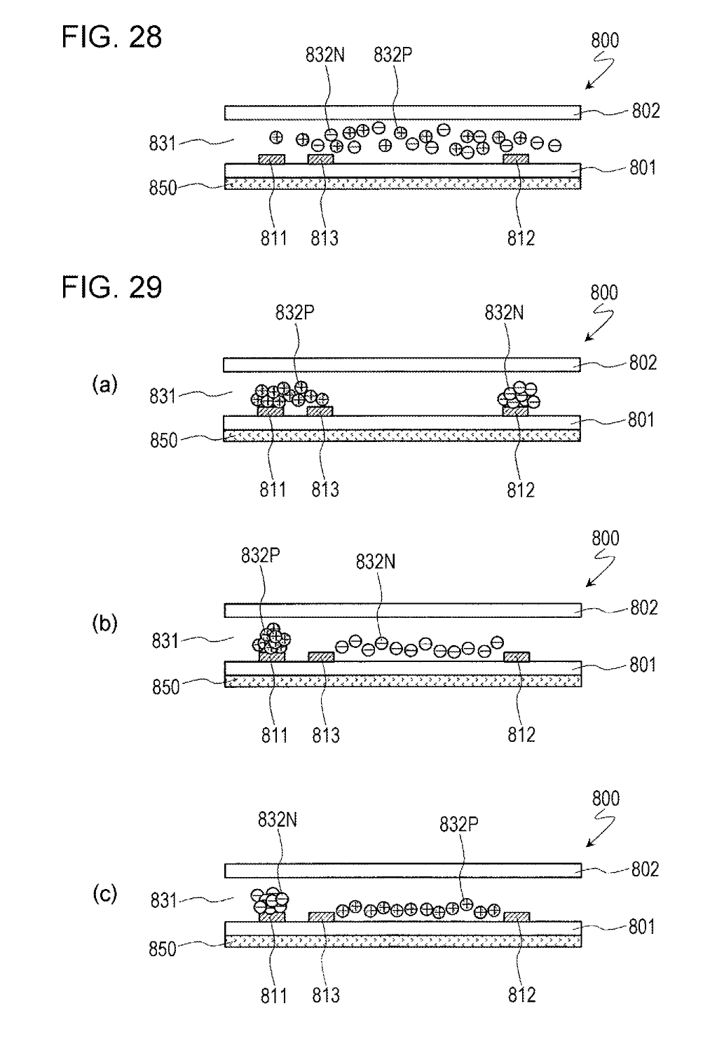

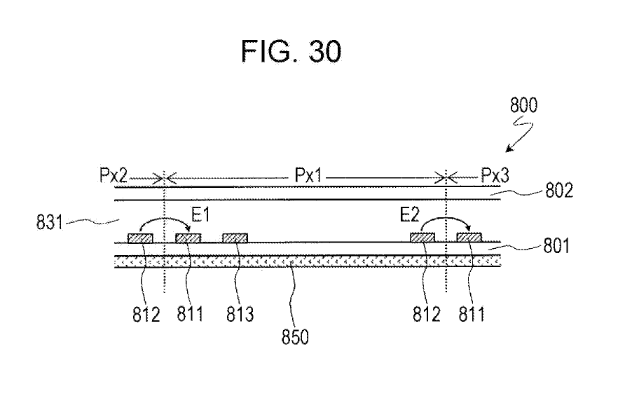

FIG. 27 illustrates an electrophoretic element (display device) 300 in the present embodiment. FIG. 27 is a cross-sectional view schematically illustrating five pixels Px (the first pixel Px1, the second pixel Px2, the third pixel Px3, a fourth pixel Px4, and a fifth pixel Px5 that are arranged so as to be continuous along the row direction) of the electrophoretic element 300. The following description will focus on how the electrophoretic element 300 of the present embodiment differs from the electrophoretic element 100 of Embodiment 1.

The first substrate 10 of the electrophoretic element 300 includes, in each of the pixels Px, three (three types of) electrodes 11, 12, and 13 to which mutually different potentials are capable of being applied. The above-described three electrodes, specifically, the first electrode 11, the second electrode 12, and the third electrode 13 are arranged in this order along a certain. direction (direction from a left side to a right side in FIG. 27) which is parallel to the substrate surface of the first substrate 10.

Moreover, the electrophoretic layer 30 of the electrophoretic element 300 includes green electrophoretic particles (green particles) 32G and magenta electrophoretic particles (magenta particles) 32M. The green particles 32G and the magenta particles 32M are charged with mutually different polarity. Specifically, the green particles 32G are charged with negative polarity and the magenta particles 32M are charged with positive polarity. The light reflecting layer 50 that is white is provided closer to the rear surface than the electrophoretic layer 30.

By controlling potentials of the three electrodes 11, 12, and 13, the electrophoretic element 300 is able to apply a horizontal electric field to the electrophoretic layer 30, and it is thereby possible to perform switching among a state (green display state) where only the green particles 32G are positioned in the opening region R1, a state (magenta display state) where only the magenta particles 32M are positioned in the opening region R1, a state (black display state) where both the green particles 32G and the magenta particles 32M are positioned in the opening region R1, and a state (white display state) where none of the green particles 32G and the magenta particles 32M is positioned in the opening region R1.

FIG. 27 exemplifies a case where the first pixel Px1, the second pixel Px2, the third pixel Px3, the fourth pixel Px4, and the fifth pixel Px5 are in the black display state, the magenta display state, the white display state, the green display state, and the white display state, respectively. Moreover, FIG. 27 also illustrates which of a predetermined negative potential (−A [V]), the ground potential (0 [V]), and a predetermined positive potential (+A [V]) each of the potential V1 of the first electrode 11, the potential V2 of the second electrode 12, and the potential V3 of the third electrode 13 is in each of the states.

In the present embodiment, the column part 40a of the partition wall 40 covers two electrodes 11 and 13 as illustrated in FIG. 27. For example, the column part 40a positioned between the first pixel Px1 and the second pixel Px2 in FIG. 27 covers the third electrode 13 (which is an electrode closest to the second pixel Px2 among the three electrodes 11, 12, and 13 of the first pixel Px1) of the first pixel Px1 and the first electrode 11 (which is an electrode closest to the first pixel Px1 among the three electrodes 11, 12, and 13 of the second pixel Px2) of the second pixel Px2. That is, the column part 40a of the partition wall 40 covers a pair of electrodes, which is composed of one electrode among three electrodes 11, 12, and 13 of one pixel Px of two pixels Px that are adjacent to each other via the column part 40a and one electrode of three electrodes 11, 12, and 13 of the other pixel Px. Therefore, similarly to Embodiment 1, it is possible to cut an influence of an electric field of an adjacent pixel within the partition wall 40, thus making it possible to suitably perform movement (that is, a display operation) of the electrophoretic particles 32. Accordingly, occurrence of crosstalk is prevented.

### INDUSTRIAL APPLICABILITY

According to Embodiments of the invention, it is possible to prevent occurrence of crosstalk in an electrophoretic element using a horizontal electric field. The electrophoretic element of any of Embodiments of the invention is suitably used for a display device.

### REFERENCE SIGNS LIST

10 first substrate

10a transparent substrate

11 first electrode

12 second electrode

13 third electrode

14 fourth electrode

19 insulating layer

20 second substrate

20a transparent substrate

21 light shielding layer

21a first light shielding region.

21b second light shielding region

30 electrophoretic layer

31 dispersion medium

32 electrophoretic particle

32C cyan particle

32M magenta particle

32Y yellow particle

32B black particle

32G green particle

40 partition wall

40a column part of partition wall

40b row part of partition wall

40c connection part of partition wall

50 light reflecting layer

100, 200, 300 electrophoretic element (display device)

Px pixel

R1 opening region

1. An electrophoretic element comprising:
a first substrate and a second substrate that face each other;
an electrophoretic layer that is provided between the first substrate and the second substrate; and
a plurality of pixels that are arrayed in a matrix having a plurality of rows and a plurality of columns, and each of which includes an opening region through which light passes from the electrophoretic layer toward a front surface side, wherein
a partition wall that is provided between the first substrate and the second substrate and partitions the electrophoretic layer into individual pixels is further included,
the first substrate includes, in each of the plurality of pixels, at least three electrodes to which mutually different potentials are capable of being applied,
the partition wall includes a first part positioned between two pixels that are adjacent along one direction of a row direction and a column direction and a second part positioned between two pixels that are adjacent along the other direction of the row direction and the column direction, and
in a case where one of two pixels that are adjacent via the first part of the partition wall is set as a first pixel and the other is set as a second pixel,
the first part of the partition wall at least partially covers each of a pair of electrodes, which is composed of one electrode of at least three electrodes of the first pixel and one electrode of at least three electrodes of the second pixel.

2. The electrophoretic element according to claim 1, wherein the electrophoretic layer includes, in each of the plurality of pixels, a dispersion medium and a plurality of types of electrophoretic particles that are dispersed in the dispersion medium.

3. The electrophoretic element according to claim 2, wherein the plurality of types of electrophoretic particles include first electrophoretic particles and second electrophoretic particles that are charged with mutually same polarity and have mutually different threshold characteristics.

4. The electrophoretic element according to claim 3, wherein
the plurality of types of electrophoretic particles include third electrophoretic particles that are charged with same polarity as that of the first electrophoretic particles and the second electrophoretic particles and have threshold characteristics different from those of the first electrophoretic particles and the second electrophoretic particles, and fourth electrophoretic particles that are charged with polarity different from that of the first electrophoretic particles, the second electrophoretic particles, and the third electrophoretic particles, and
the at least three electrodes included in the first substrate are four or more electrodes to which mutually different potentials are capable of being applied.

5. The electrophoretic element according to claim 3, wherein
the plurality of types of electrophoretic particles include third electrophoretic particles and fourth electrophoretic particles that are charged with polarity different from that of the first electrophoretic particles and the second electrophoretic particles and have mutually different threshold characteristics, and
the at least three electrodes included in the first substrate are four or more electrodes to which mutually different potentials are capable of being applied.

6. The electrophoretic element according to claim 2, wherein the plurality of types of electrophoretic particles include first electrophoretic particles and second electrophoretic particles that are charged with mutually different polarity.

7. The electrophoretic element according to claim 1, wherein the plurality of types of electrophoretic particles include electrophoretic particles having a cyan color, electrophoretic particles having a magenta color, electrophoretic particles having a yellow color, and electrophoretic particles having a black color.

8. The electrophoretic element according to claim 1, wherein the pair of electrodes that are covered with the first part are arranged to extend approximately in parallel to each other.

9. The electrophoretic element according to claim 1, wherein
the first part has a shape including two sides that are approximately parallel in the other direction, as viewed from a substrate surface normal direction of the first substrate, and
each of the pair of electrodes that are covered with the first part is arranged in a vicinity of each of the two sides.

10. The electrophoretic element according to claim 1, wherein the partition wall further includes a third part that connects the first part and the second part, and a part of each of the pair of electrodes is covered with the third part.

11. The electrophoretic element according to claim 1, wherein a distance between the pair of electrodes is equal to or shorter than a distance between any two electrodes, which are adjacent to each other, among the at least three electrodes of each of the pixels.

12. The electrophoretic element according to claim 1, wherein a width of each of the electrodes, which are covered with the first part is equal to or shorter than a width of an electrode, which is not covered with the first part, among the at least three electrodes of each of the pixels.

13. The electrophoretic element according to claim 1, further comprising
a light shielding layer that is positioned closer to a front surface side than the electrophoretic layer, wherein
the light shielding layer includes a first light shielding region that overlaps with the first part of the partition wall and a second light shielding region that extends from the first light shielding region in the one direction.

14. The electrophoretic element according to claim 1, wherein each of the pair of electrodes includes a part that is not covered with the first part of the partition wall.

15. The electrophoretic element according to claim 14, wherein a width of the part of each of the pair of electrodes, which is not covered with the first part of the partition wall, is equal to or shorter than a width of a part of each of the pair of electrodes, which is covered with the first part of the partition wall.

16. The electrophoretic element according to claim 1, wherein the at least three electrodes include at least one electrode provided in the opening region.

17. The electrophoretic element according to claim 1, wherein active matrix drive is able to be performed.

18. A display device comprising the electrophoretic element according to claim 1.
